(19) United States
(12) Patent Application Publication
(10) Pub. No.: US 2024/0395759 A1
(43) Pub. Date: Nov. 28, 2024

(54) FILM-LIKE ADHESIVE FOR SEMICONDUCTORS, METHOD FOR PRODUCING FILM-LIKE ADHESIVE FOR SEMICONDUCTORS, ADHESIVE TAPE, METHOD FOR PRODUCING SEMICONDUCTOR DEVICE, AND SEMICONDUCTOR DEVICE

(71) Applicant: Resonac Corporation, Minato-ku, Tokyo (JP)

(72) Inventors: Hiroyuki ISHIGE, Minato-ku, Tokyo (JP); Ryosuke KIMURA, Minato-ku, Tokyo (JP); Makoto SATO, Minato-ku, Tokyo (JP); Keisuke OHKUBO, Minato-ku, Tokyo (JP)

(21) Appl. No.: 18/697,008

(22) PCT Filed: Oct. 18, 2022
(86) PCT No.: PCT/JP2022/038799

§ 371 Date: Mar. 29, 2024

(30) Foreign Application Priority Data
Oct. 29, 2021 (JP) 2021-177355

(51) Int. Cl. H01L 23/00; C09J 7/30; C09J 11/06; C09J 163/10; H01L 21/304; H01L 21/683

(52) U.S. Cl. CPC H01L 24/29; C09J 7/30; C09J 11/06; C09J 163/10; H01L 21/304; H01L 21/6836; H01L 24/32; H01L 24/73; H01L 24/83; H01L 24/94; C09J 2203/326; C09J 2301/208; C09J 2301/416; H01L 24/16; H01L 2221/68327; H01L 2224/16225; H01L 2224/2919; H01L 2224/2957; H01L 2224/2969; H01L 2224/32225; H01L 2224/73204; H01L 2224/83862; H01L 2224/83874; H01L 2224/94; H01L 2924/3511; H01L 2924/3512

(57) ABSTRACT

A film-shaped adhesive having a first adhesive region and a second adhesive region along a thickness direction, in which the first adhesive region has photocurability and thermosetting properties, and the second adhesive region has thermosetting properties but does not have photocurability.

### TECHNICAL FIELD

The present disclosure relates to a film-shaped adhesive for semiconductors, a method for producing a film-shaped adhesive for semiconductors, an adhesive tape, a method for producing a semiconductor device, and a semiconductor device.

### BACKGROUND ART

Wire bonding systems of using fine metal wires such as gold wires have been hitherto widely applied to connect semiconductor chips and substrates. Meanwhile, in order to respond to the requests for higher functionalization, higher integration, higher speed, and the like for semiconductor devices, a flip-chip connection system (FC connection system) in which a semiconductor chip and a substrate are directly connected by forming conductive protrusions called bumps on the semiconductor chip or the substrate, is becoming widespread.

For example, with regard to the connection between a semiconductor chip and a substrate, a COB (Chip On Board) type connection system that is actively used in BGA (Ball Grid Array), CSP (Chip Size Package), and the like, also corresponds to the FC connection system. In addition, the FC connection system is also widely used in a COC (Chip On Chip) type connection system in which semiconductor chips are connected by forming connecting parts (for example, bumps and wiring lines) on the semiconductor chips.

In packages where further size reduction, thickness reduction, and high functionalization are strongly required, chip stack type packages, POP (Package On Package), TSV (Through-Silicon Via), and the like, in which chips are stacked into multi-stages by using the above-mentioned connection systems, are also beginning to become widespread. Since such a technology of stacking into multi-stages allows three-dimensional arrangement of semiconductor chips and the like, packages can be made smaller as compared to techniques of arranging semiconductor chips and the like two-dimensionally. In addition, since the technology of stacking into multi-stages is also effective in improving semiconductor performance, reducing noise, reducing mounting area, and saving electric power, the technology is attracting attention as a next-generation semiconductor wiring technology.

From the viewpoint of improving productivity, COW (Chip On Wafer) by which semiconductor packages are produced by pressure-bonding (connecting) semiconductor chips on a semiconductor wafer and then singularizing the semiconductor wafer, is also attracting attention. From a similar viewpoint, a gang bonding system in which a plurality of semiconductor chips are aligned and temporarily bonded on a semiconductor wafer or a map board, and then the plurality of semiconductor chips are permanently pressure-bonded all at once to secure connection, is also attracting attention.

For the connection between connecting members such as semiconductor chips as described above, thermosetting film-shaped adhesives are used (see, for example, Patent Literature 1). A film-shaped adhesive is cured by performing heating at the time of connection (at the time of pressure-bonding); however, in a case where the film-shaped adhesive is cured before connecting parts of connecting members are brought into contact with each other by pressure-bonding, the assembly is in a state in which a cure product of the adhesive is interposed between the connecting parts, and connection failure occurs, so that the adhesive needs to exhibit appropriate fluidity at the time of connection.

### CITATION LIST

### Patent Literature

Patent Literature 1: Japanese Unexamined Patent Publication No. 2008-294382

### SUMMARY OF INVENTION

### Technical Problem

In recent years, along with high functionalization and high integration of packages, the gaps between layers and the pitch between wires have become narrower, and therefore, the adhesive having fluidity at the time of connection easily protrudes from the edges of connecting members (for example, semiconductor chips), so that protruding parts called fillet are becoming more likely to be formed. Since such fillet may cause damage to the connecting members, there is a demand for the development of a technique for reducing the amount of fillet generated while ensuring conductivity (connection reliability) between the connecting members.

Thus, it is a main object of the present disclosure to provide a film-shaped adhesive for semiconductors that can suppress the amount of fillet generated while ensuring sufficient connection reliability.

### Solution to Problem

The present disclosure provides the following [1] to [18].

[1] A film-shaped adhesive for semiconductors, including a first adhesive region and a second adhesive region along a thickness direction,
in which the first adhesive region has photocurability and thermosetting properties, and
the second adhesive region has thermosetting properties but does not have photocurability.

[2] The film-shaped adhesive for semiconductors according to [1], in which the first adhesive region contains a photopolymerizable compound, a photopolymerization initiator, a thermosetting resin, and a thermal curing agent.

[3] The film-shaped adhesive for semiconductors according to [2], in which the photopolymerizable compound is a radically polymerizable compound, and the photopolymerization initiator is a photoradical polymerization initiator.

[4] The film-shaped adhesive for semiconductors according to [3], in which the radically polymerizable compound includes a (meth)acrylic compound.

[5] The film-shaped adhesive for semiconductors according to any one of [2] to [4], in which the thermosetting resin includes an epoxy resin.

[6] The film-shaped adhesive for semiconductors according to [5], in which the thermal curing agent includes an imidazole-based curing agent.

[7] The film-shaped adhesive for semiconductors according to [6], in which the imidazole-based curing agent has a triazine ring.

[8] The film-shaped adhesive for semiconductors according to any one of [2] to [7], in which a ratio of a content of the thermosetting resin with respect to a content of the photopolymerizable compound in the first adhesive region is 3 to 11 in terms of mass ratio.

[9] The film-shaped adhesive for semiconductors according to any one of [1] to [8], in which the second adhesive region contains a thermosetting resin, a thermal curing agent, and a flux compound.

[10] The film-shaped adhesive for semiconductors according to [9], in which the flux compound has two or more carboxy groups.

[11] The film-shaped adhesive for semiconductors according to any one of [1] to [10], in which the second adhesive region has a thickness of 0.5 to 2 times a thickness of the first adhesive region.

[12] The film-shaped adhesive for semiconductors according to any one of [1] to [11], in which the film-shaped adhesive is used for joining a semiconductor chip and a base and sealing a gap between the semiconductor chip and the base.

[13] A method for producing the film-shaped adhesive for semiconductors according to any one of [1] to [12], the method including:
a step of providing any one of a first adhesive layer having photocurability and thermosetting properties and a second adhesive layer having thermosetting properties but not having photocurability, on the other.

[14] An adhesive tape including:
the film-shaped adhesive for semiconductors according to any one of [1] to [12]; and
a back grinding tape provided on the film-shaped adhesive for semiconductors, the back grinding tape being provided on an opposite side of the first adhesive region side as viewed from the second adhesive region.

[15] A method for producing a semiconductor device, the method including:
a light irradiation step of irradiating the first adhesive region of the film-shaped adhesive for semiconductors according to any one of [1] to [12] with light; and
a step of heating and joining a semiconductor chip and a base in a state in which the semiconductor chip and the base are arranged, with the film-shaped adhesive for semiconductors after light irradiation interposed therebetween, such that connecting parts thereof face each other,
in which the light irradiation step is carried out in a state in which the film-shaped adhesive for semiconductors is stuck, from a side of the first adhesive region, to a connecting surface of the semiconductor chip or a precursor thereof, or a connecting surface of the base or a precursor thereof.

[16] The method for producing a semiconductor device according to [15], further including:
a step of preparing an adhesive tape including the film-shaped adhesive for semiconductors and a back grinding tape provided on the film-shaped adhesive for semiconductors, the back grinding tape being provided on an opposite side of the first adhesive region side as viewed from the second adhesive region;
a lamination step of sticking the adhesive tape to a connecting surface of a precursor of the semiconductor chip or a precursor of the base from a side of the film-shaped adhesive for semiconductors; and
a back grinding step of grinding the precursor to which the adhesive tape is stuck, from an opposite side of the adhesive tape.

[17] The method for producing a semiconductor device according to [17], in which the light irradiation step is carried out after removing the back grinding tape after the back grinding step.

[18] A semiconductor device including: a semiconductor chip having a first connecting part; a base having a second connecting part electrically connected to the first connecting part; and a sealing part joining the semiconductor chip and the base and filling a gap between the semiconductor chip and the base, in which the sealing part is a cured product of the film-shaped adhesive for semiconductors according to any one of [1] to [12].

### Advantageous Effects of Invention

According to the present disclosure, a film-shaped adhesive for semiconductors, which can suppress the amount of fillet generated while ensuring sufficient connection reliability, can be provided.

### BRIEF DESCRIPTION OF DRAWINGS

FIG. 1 is a schematic cross-sectional view illustrating an embodiment of a film-shaped adhesive for semiconductors according to the present disclosure.

FIG. 2 is schematic cross-sectional views illustrating an embodiment of a semiconductor device according to the present disclosure.

FIG. 3 is a schematic cross-sectional view illustrating another embodiment of the semiconductor device according to the present disclosure.

FIG. 4 is a process cross-sectional view schematically illustrating an embodiment of a method for producing a semiconductor device according to the present disclosure.

FIG. 5 is a process cross-sectional view schematically illustrating an embodiment of the method for producing a semiconductor device according to the present disclosure.

FIG. 6 is a process cross-sectional view schematically illustrating an embodiment of the method for producing a semiconductor device according to the present disclosure.

FIG. 7 is a process cross-sectional view schematically illustrating an embodiment of the method for producing a semiconductor device according to the present disclosure.

FIG. 8 is a process cross-sectional view schematically illustrating an embodiment of the method for producing a semiconductor device according to the present disclosure.

FIG. 9 is a process cross-sectional view schematically illustrating an embodiment of the method for producing a semiconductor device according to the present disclosure.

### DESCRIPTION OF EMBODIMENTS

According to the present specification, the term “(meth)acryl” means at least one of acryl and methacryl corresponding thereto. The same also applies to other similar expressions such as “(meth)acryloyl” and “(meth)acrylate”. In addition, a numerical value range expressed by using the term “to” represents a range including the numerical values described before and after the term “to” as the minimum value and the maximum value, respectively. With regard to a numerical value range described in the present specification, the upper limit value or the lower limit value of the numerical value range may be replaced with a value indicated in the Examples. Furthermore, upper limit values and lower limit values that are described individually can be combined arbitrarily. Unless particularly stated otherwise, the materials that will be mentioned below may be used singly, or two or more kinds thereof may be used in combination. In a case where there are a plurality of substances corresponding to each component in the composition, unless particularly stated otherwise, the content of each component in the composition means the total amount of the plurality of substances present in the composition.

Embodiments of the present disclosure will be described in detail below with reference to the drawings as needed. In the drawings, the same or equivalent parts are assigned with the same reference numerals, and duplicate descriptions will not be repeated. In addition, unless particularly stated otherwise, the positional relationships such as upper, lower, right, and left are based on the positional relationships shown in the drawings. Furthermore, the dimensional ratios in the drawings are not limited to the ratios shown in the drawings.

### <Film-Shaped Adhesive for Semiconductors>

The film-shaped adhesive for semiconductors (hereinafter, simply referred to as “film-shaped adhesive”) according to one embodiment is an adhesive used for connection (joining) and sealing of connecting members such as semiconductor chips, and for example, the film-shaped adhesive is used for joining a semiconductor chip and a base and sealing a gap between the semiconductor chip and the base.

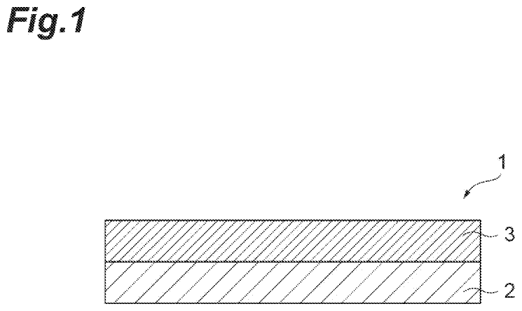

FIG. 1 is a schematic cross-sectional view illustrating a film-shaped adhesive according to an embodiment. The film-shaped adhesive 1 shown in the same drawing has a first adhesive region 2 having photocurability and thermosetting properties along the thickness direction (up-to-down direction in FIG. 1) and a second adhesive region 3 having thermosetting properties but not having photocurability. In the following description, the adhesive constituting the first adhesive region 2 is referred to as first adhesive, and the adhesive constituting the second adhesive region 3 is referred to as second adhesive.

The first adhesive region 2 and the second adhesive region 3 have predetermined thicknesses and are extended, for example, as shown in FIG. 1, along the principal plane direction (left-to-right direction in FIG. 1) of the film-shaped adhesive 1. The boundary between the first adhesive region 2 and the second adhesive region 3 is not necessarily clear and may not be visually recognizable. In FIG. 1, the first adhesive region 2 and the second adhesive region 3 are adjacent to each other; however, there may be a region different from the first adhesive region 2 and the second adhesive region 3 (for example, a region including a mixture of the first adhesive and the second adhesive) between the first adhesive region 2 and the second adhesive region 3.

With regard to the film-shaped adhesive 1, since the first adhesive region 2 has photocurability, the film-shaped adhesive 1 easily becomes partially fluidized by light irradiation. Specifically, the fluidity of the first adhesive region 2 can be lowered by, for example, sticking the film-shaped adhesive 1 to one of two connecting members (or precursors thereof) and then performing light irradiation. Therefore, when the film-shaped adhesive 1 is used, excessive flow of the adhesive when performing connection between connecting members can be suppressed, and the amount of fillet generated can be suppressed. On the other hand, since the second adhesive region 3 of the film-shaped adhesive 1 does not have photocurability, according to a method of sticking the film-shaped adhesive 1 to one of the connecting members from the first adhesive region 2 side (opposite side of the second adhesive region 3 side) and subsequently performing light irradiation, even after light irradiation, the fluidity of the other connecting member side (that is, second adhesive region 3 side) can be maintained. Therefore, when the film-shaped adhesive 1 is used, it is also possible to ensure sufficient connection reliability.

In addition, the first adhesive region 2 has thermosetting properties in addition to photocurability, and is designed such that the first adhesive region 2 can be further cured (thermally cured) by heating while maintaining moderate fluidity even after photocuring. Accordingly, even in a case where the surface of the connecting part is covered with the adhesive at the time of sticking the film-shaped adhesive 1, since the adhesive flows and is removed at the time of connection, a cured product of the adhesive is less likely to remain between the connecting parts after connection. The fact that the first adhesive is designed in this way is also one of the reasons why sufficient connection reliability is obtained by the film-shaped adhesive 1. The fluidity of the adhesive as a whole at the time of connection can be changed by adjusting the thickness, composition, amount of light irradiation, and the like of the first adhesive region 2 and also by adjusting the thickness, composition, and the like of the second adhesive region 3. As a result, for example, it is possible to reduce the quantity of voids generated and to ensure satisfactory sealing properties (filling properties of the adhesive).

Furthermore, in the case of simply using an adhesive having low fluidity, the adhesive may not sufficiently fill in the space between the connecting parts of the connecting members and may cause defects such as voids; however, in the above-described method, since the film-shaped adhesive 1 is stuck to the connecting members before the fluidity of the first adhesive region 2 is decreased (that is, before performing light irradiation), when the film-shaped adhesive 1 is used, the occurrence of such defects can be suppressed.

Meanwhile, metal joining is generally used for the connection between connecting members, from the viewpoint of sufficiently ensuring connection reliability (for example, insulation reliability). Examples of a main metal used for the connecting parts (for example, bumps and wiring lines) of the connecting members include solder, tin, gold, silver, copper, and nickel, and conductive materials including a plurality of kinds of these are also used. On the surface of the connecting parts, impurities may be generated as the above-described metals are oxidized to generate an oxide film, and as impurities such as oxides adhere to the surface. When such impurities remain, there is concern that the connection reliability between the connecting members may be decreased, and the advantage of employing the above-mentioned connection systems may be impaired. Thus, in order to remove the above-mentioned oxide film and impurities, a flux compound may be included into the film-shaped adhesive 1. As described above, since the film-shaped adhesive 1 is stuck to one connecting member from the first adhesive region 2 side, and the second adhesive region 3 side is used so as to flow over the connecting surface of the other connecting member, it is preferable that the flux compound is contained in the second adhesive region 3.

### (First Adhesive Region)

The first adhesive region contains, for example, a photopolymerizable compound, a photopolymerization initiator, a thermosetting resin, and a thermal curing agent. Here, the “photopolymerizable compound” means a compound that is polymerized by an active species (a radical, a cation, or an anion) generated by a photopolymerization initiator upon irradiation with light (for example, ultraviolet light), and the “thermosetting resin” means a compound that is cured by heat through a reaction with a thermal curing agent.

### [Photopolymerizable Compound]

The photopolymerizable compound may be a radically polymerizable compound, may be a cationically polymerizable compound, or may be an anionically polymerizable compound. The polymerizability of the photopolymerizable compound may be selected based on the relationship with the curability of the thermosetting resin and the thermal curing agent so as not to inhibit the reaction between the thermosetting resin and the thermal curing agent. For example, in a case where the thermosetting resin has cationic curability or anionic curability, it is preferable to use a radically polymerizable compound as the photopolymerizable compound.

From the viewpoint of the reaction rate, the photopolymerizable compound is preferably a radically polymerizable compound. In this case, a photoradical polymerization initiator is used as the photopolymerization initiator.

Examples of the radically polymerizable compound include a (meth)acrylic compound and a vinyl compound. From the viewpoint of being excellent in terms of durability, electrical insulation properties, and heat resistance, the radically polymerizable compound is preferably a (meth)acrylic compound. The (meth)acrylic compound may be a compound having one or more (meth)acryloyl groups in the molecule. As the (meth)acrylic compound, for example, (meth)acrylic compounds containing a skeleton of bisphenol A type, bisphenol F type, naphthalene type, phenol novolac type, cresol novolac type, phenol aralkyl type, biphenyl type, triphenylmethane type, dicyclopentadiene type, fluorene type, adamantane type, or isocyanuric acid type; various polyfunctional (meth)acrylic compounds (excluding (meth)acrylic compounds containing the above-described skeletons); and the like can be used. Examples of the polyfunctional (meth)acrylic compounds include pentaerythritol tri(meth)acrylate, dipentaerythritol poly(meth)acrylates (dipentaerythritol penta(meth)acrylate, dipentaerythritol hexa(meth)acrylate, and the like), and trimethylolpropane di(meth)acrylate. Among these, a polyfunctional (meth)acrylic compound is preferred, and a dipentaerythritol poly(meth)acrylate is more preferred. The number of functional groups (number of (meth)acryloyl groups) of the polyfunctional (meth)acrylic compound is preferably 2 to 8, more preferably 3 to 7, and even more preferably 4 to 6.

The molecular weight of the photopolymerizable compound is, for example, 400 to 2000. The molecular weight of the photopolymerizable compound is preferably less than 2000, and more preferably 1000 or less. As the molecular weight of the photopolymerizable compound is smaller, the reaction easily proceeds, and the curing reaction ratio is increased.

The photopolymerizable compounds can be used singly or in combination of two or more kinds thereof.

From the viewpoint of further reducing the amount of fillet generated, the content of the photopolymerizable compound in the first adhesive region 2 is preferably 1% by mass or more, more preferably 3% by mass or more, and even more preferably 5% by mass or more, based on the total amount of the first adhesive. From the viewpoint of improving sealing properties and from the viewpoint of suppressing the generation of voids, the content of the polymerizable compound is preferably 10% by mass or less, more preferably 7% by mass or less, or even more preferably 5% by mass or less, based on the total amount of the first adhesive. From these viewpoints, the content of the photopolymerizable compound is preferably 1 to 10% by mass, more preferably 3 to 7% by mass, and even more preferably 3 to 5% by mass, based on the total amount of the first adhesive.

### [Photopolymerization Initiator]

The photopolymerization initiator may be a photoradical polymerization initiator, a cationic polymerization initiator, or an anionic polymerization initiator. The photopolymerization initiator can be selected depending on the type of the photopolymerizable compound, and for the same reason as that of the photopolymerizable compound, a photoradical polymerization initiator is preferably used.

The photoradical polymerization initiator is a compound that is decomposed upon irradiation with, for example, light including a wavelength in the range of 150 to 750 nm, preferably light including a wavelength in the range of 254 to 405 nm, and more preferably light including a wavelength at 365 nm (for example, ultraviolet light), and generates free radicals. As the photoradical polymerization initiator, one compound may be used alone, or a plurality of kinds of compounds may be used in combination.

Examples of the photoradical polymerization initiator include photopolymerization initiators having structures such as an oxime ester structure, a bisimidazole structure, an acridine structure, an α-aminoalkylphenone structure, an aminobenzophenone structure, an N-phenylglycine structure, an acylphosphine oxide structure, a benzyl dimethyl ketal structure, an α-hydroxyalkylphenone structure, and an α-hydroxyacetophenone structure. Among these, from the viewpoint of reactivity and from the viewpoint that the amount of fillet generated is more easily reduced, it is preferable to use a compound having at least one structure selected from the group consisting of an acylphosphine oxide structure, an α-hydroxyalkylphenone structure, and an α-hydroxyacetophenone structure, it is more preferable to use a compound having at least one structure selected from the group consisting of an acylphosphine oxide structure and an α-hydroxyacetophenone structure, and it is even more preferable to use a compound having an acylphosphine oxide structure.

Specific examples of a compound having an acylphosphine oxide structure include bis(2,6-dimethoxybenzoyl)-2,4,4-trimethyl-pentylphosphine oxide, phenylbis(2,4,6-trimethylbenzoyl)phosphine oxide, and 2,4,6-trimethylbenzoyl-diphenyl-phosphine oxide.

Specific examples of a compound having an α-hydroxyalkylphenone structure include 1-hydroxycyclohexyl phenyl ketone.

Specific examples of a compound having an α-hydroxyacetophenone structure include 2-hydroxy-1-(4-(4-(2-hydroxy-2-methylpropionyl)benzyl)phenyl)-2-methylpropan-1-one.

Among those described above, it is preferable to use at least one compound selected from the group consisting of 1-hydroxycyclohexyl phenyl ketone, phenylbis(2,4,6-trimethylbenzoyl)phosphine oxide, and 2-hydroxy-1-(4-(4-(2-hydroxy-2-methylpropionyl)benzyl)phenyl)-2-methylpropan-1-one, it is more preferable to use at least one compound selected from the group consisting of phenylbis(2,4,6-trimethylbenzoyl)phosphine oxide and 2-hydroxy-1-(4-(4-(2-hydroxy-2-methylpropionyl)benzyl)phenyl)-2-methylpropan-1-one, and it is even more preferable to use phenylbis(2,4,6-trimethylbenzoyl)phosphine oxide.

From the viewpoint of suppressing volatilization caused by heat at the time of film formation, sticking, and the like, the molecular weight of the photoradical polymerization initiator is preferably 400 or more (for example, 300 to 600).

From the viewpoint that it is easy to allow curing to sufficiently proceed, the content of the photoradical polymerization initiator in the first adhesive region 2 is preferably 0.1 parts by mass or more, more preferably 0.5 parts by mass or more, and even more preferably 1 part by mass or more, with respect to 100 parts by mass of the photopolymerizable compound. From the viewpoint of suppressing shortening of the molecular chain due to rapid progress of the curing reaction and remaining of unreacted groups, the content of the photoradical polymerization initiator is preferably 5 parts by mass or less, more preferably 3 parts by mass or less, and even more preferably 1.5 parts by mass or less, with respect to 100 parts by mass of the photopolymerizable compound. From these viewpoints, the content of the photoradical polymerization initiator is preferably 0.1 to 5 parts by mass, more preferably 0.5 to 3 parts by mass, and even more preferably 0.5 to 1.5 parts by mass, with respect to 100 parts by mass of the photopolymerizable compound.

### [Thermosetting Resin]

Examples of the thermosetting resin include an epoxy resin, a phenol resin (except for the case of being contained as a curing agent), and an acrylic resin. Among these, an epoxy resin is preferably used. The content of the epoxy resin in the thermosetting resin is preferably 80% by mass or more, and more preferably 90% by mass or more, based on the total amount of the thermosetting resin. The content of the epoxy resin may be 100% by mass based on the total amount of the thermosetting resin.

The epoxy resin is a compound having two or more epoxy groups in the molecule. As the epoxy resin, for example, a bisphenol A type epoxy resin, a bisphenol F type epoxy resin, a naphthalene type epoxy resin, a phenol novolac type epoxy resin, a cresol novolac type epoxy resin, a phenol aralkyl type epoxy resin, a biphenyl type epoxy resin, a triphenylmethane type epoxy resin, a triphenolmethane type epoxy resin, a dicyclopentadiene type epoxy resin, and various polyfunctional epoxy resins can be used. These can be used singly or as mixtures of two or more kinds thereof. Among these, in a case where a triphenolmethane type epoxy resin (triphenolmethane skeleton-containing epoxy resin) is used, the amount of fillet generated tends to be further reduced.

Regarding the epoxy resin, from the viewpoint of suppressing the epoxy resin from being decomposed and generating volatile components at the time of connection at a high temperature, in a case where the temperature at the time of connection is 250° C., it is preferable to use an epoxy resin having a thermal weight loss rate at 250° C. of 5% or less, and in a case where the temperature at the time of connection is 300° C., it is preferable to use an epoxy resin having a thermal weight loss rate at 300° C. of 5% or less.

Regarding the epoxy resin, from the viewpoint that it is easy to suppress the occurrence of cracks and fissures on the film surface, an epoxy resin that is liquid at 25° C. (hereinafter, simply referred to as “liquid epoxy resin”) may also be used. Here, the phrase “liquid at 25° C.” means that the viscosity at 25° C. as measured with an E type viscometer is 400 Pa·s or less. Examples of the liquid epoxy resin include glycidyl ether of a bisphenol A type resin, glycidyl ether of a bisphenol AD type resin, glycidyl ether of a bisphenol S type resin, glycidyl ether of a bisphenol F type resin, glycidyl ether of a hydrogenated bisphenol A type resin, glycidyl ether of an ethylene oxide adduct bisphenol A type resin, glycidyl ether of a propylene oxide adduct bisphenol A type resin, glycidyl ether of a naphthalene resin, and a trifunctional or tetrafunctional glycidyl amine.

From the viewpoint that it is easy to suppress the occurrence of cracks and fissures on the film surface, the content of the liquid epoxy resin in the thermosetting resin is preferably 5% by mass or more, more preferably 10% by mass or more, and even more preferably 20% by mass or more, based on the total amount of the thermosetting resin. From the viewpoint that it is easy to suppress excessive increase in the tackiness of the film and from the viewpoint that it is easy to suppress edge fusion, the content of the liquid epoxy resin is preferably 30% by mass or less, more preferably 20% by mass or less, or even more preferably 10% by mass or less, based on the total amount of the thermosetting resin.

The reactive functional group equivalent of the thermosetting resin (for example, epoxy equivalent of the epoxy resin) may be 100 to 3000 g/eq, or may be 100 to 2000 g/eq or 100 to 1500 g/eq. When the reactive functional group equivalent is in the above-described range, the balance between reactivity and fluidity during heating is likely to be satisfactory.

From the viewpoint of allowing the generation of fillet to be easily suppressed, the content of the thermosetting resin in the first adhesive region 2 is preferably 25% by mass or more, more preferably 30% by mass or more, and even more preferably 35% by mass or more, based on the total amount of the first adhesive. From the viewpoint that satisfactory sealing properties are likely to be obtained, and from the viewpoint that the generation of voids is easily suppressed, the content of the thermosetting resin is preferably 50% by mass or less, more preferably 45% by mass or less, and even more preferably 40% by mass or less, based on the total amount of the first adhesive.

The content of the thermosetting resin may be set based on the relationship with the content of the photopolymerizable compound. When the ratio of the content of the thermosetting resin with respect to the content of the photopolymerizable compound in the first adhesive region 2 is 3 to 11 in terms of mass ratio, high connection reliability is likely to be obtained, and the amount of fillet generated tends to be further reduced. From the viewpoint that the amount of fillet generated is further reduced, the above-described ratio may be 5 or more, 7 or more, or 9 or more, and in addition to the above-described effects, the ratio may be 10 or less from the viewpoint that satisfactory sealing properties are likely to be obtained, and from the viewpoint that the generation of voids is easily suppressed.

### [Thermal Curing Agent]

As the thermal curing agent, known curing agents that are known as curing agents for thermosetting resins can be used. The thermal curing agent also includes materials that are generally known as curing accelerators. In a case where an epoxy resin is used as the thermosetting resin, as the thermal curing agent, for example, a phenol resin-based curing agent, an acid anhydride-based curing agent, an amine-based curing agent, an imidazole-based curing agent, and a phosphine-based curing agent can be used. Among these, a phenol resin-based curing agent, an acid anhydride-based curing agent, an amine-based curing agent, and an imidazole-based curing agent exhibit flux activity that suppresses generation of an oxide film at the connecting parts, and therefore, the connection reliability can be improved by using these thermal curing agents. From the viewpoint that curing can be rapidly carried out in the case of performing heating at a low temperature, it is preferable to use an imidazole-based curing agent.

Examples of the imidazole-based curing agent include 2-phenylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-trimellitate 1-cyanoethyl-2-phenylimidazolium undecylimidazole trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-phenyl-4,5-dihydroxymethylimidazole, 2-phenyl-4-methyl-5-hydroxymethylimidazole, and an adduct of an epoxy resin and an imidazole. In addition, latent curing agents in which these curing agents are microencapsulated can also be used. These can be used singly or in combination of two or more kinds thereof. Among these, from the viewpoint that more satisfactory sealing properties are likely to be obtained, and from the viewpoint that the generation of voids is easily suppressed, a compound having a triazine ring is preferably used.

From the viewpoint that the curability at the time of heating is improved, the content of the thermal curing agent in the first adhesive region 2 is preferably 1 part by mass or more, more preferably 2 parts by mass or more, and even more preferably 3 parts by mass or more, with respect to 100 parts by mass of the thermosetting resin. From the viewpoint that intervention of the first adhesive into the space between the connecting parts can be made more difficult to occur, the content of the thermal curing agent is preferably 10 parts by mass or less, more preferably 7 parts by mass or less, and even more preferably 5 parts by mass or less, with respect to 100 parts by mass of the thermosetting resin.

### [Other Components]

With regard to the first adhesive region 2, examples of components other than those described above include a thermoplastic resin and a filler (filler).

A thermoplastic resin contributes to the improvement in heat resistance and the improvement in film-forming properties. Examples of the thermoplastic resin include a phenoxy resin, a polyimide resin, a polyamide resin, a polycarbodiimide resin, a cyanate ester resin, an acrylic resin, a polyester resin, a polyethylene resin, a polyether sulfone resin, a polyetherimide resin, a polyvinyl acetal resin, a urethane resin, and an acrylic rubber. Among these, from the viewpoint that excellent heat resistance and film-forming properties are likely to be obtained, a phenoxy resin, a polyimide resin, an acrylic rubber, a cyanate ester resin, and a polycarbodiimide resin are preferred, and a phenoxy resin, a polyimide resin, and an acrylic rubber are more preferred. These thermoplastic resins can be used singly or as mixture or copolymers of two or more kinds thereof.

The weight average molecular weight of the thermoplastic resin is, for example, 10000 or more and may be 20000 or more or 30000 or more. When such a thermoplastic resin is used, the heat resistance and film-forming properties of the first adhesive can be further improved. From the viewpoint that an effect of improving heat resistance is likely to be obtained, the weight average molecular weight of the thermoplastic resin may be 1000000 or less or may be 500000 or less. Incidentally, the weight average molecular weight as used in the present specification means a weight average molecular weight obtained when measured by using high performance liquid chromatography (manufactured by Shimadzu Corporation, trade name: C-R4A), relative to polystyrene standards. For the measurement, for example, the following conditions can be used.
Detector: LV4000 UV Detector (manufactured by Hitachi, Ltd., trade name)
Pump: L6000 Pump (manufactured by Hitachi, Ltd., trade name)
Column: Gelpack GL-S300MDT-5 (two in total) (manufactured by Hitachi, Ltd., trade name)
Eluent: THF/DMF=1/1 (volume ratio)+LiBr (0.03 mol/L)+H3PO4 (0.06 mol/L)
Flow rate: 1 mL/min

From the viewpoint of having excellent stickability of the film-shaped adhesive 1 to connecting members (for example, semiconductor chips), the glass transition temperature (Tg) of the thermoplastic resin is preferably 120° C. or lower, more preferably 100° C. or lower, and even more preferably 85° C. or lower. The above-described Tg is a Tg obtained when measured using a DSC (manufactured by Perkin Elmer, Inc., trade name: DSC-7 type) under the conditions of a sample amount of 10 mg, a temperature increase rate of 10° C./min, and a measurement atmosphere of air.

From the viewpoint that the heat resistance and film-forming properties of the first adhesive are likely to be improved, the content of the thermoplastic resin in the first adhesive region 2 is preferably 5% by mass or more, more preferably 7% by mass or more, and even more preferably 10% by mass or more, based on the total amount of the first adhesive. From the viewpoint of allowing the generation of fillet to be easily suppressed, the content of the thermoplastic resin is preferably 30% by mass or less, more preferably 25% by mass or less, and even more preferably 20% by mass or less, based on the total amount of the first adhesive.

A filler is effective for controlling the viscosity of the first adhesive, the physical properties of a cured product of the first adhesive, and the like. Specifically, by using a filler, suppression of void generation at the time of connection, reduction of the coefficient of moisture absorption of a cured product of the first adhesive, and the like can be promoted. The filler may be an inorganic filler (inorganic particles) or an organic filler (organic particles). Examples of the inorganic filler include insulating inorganic fillers such as glass, silica, alumina, titanium oxide, mica, and boron nitride. Among these, it is preferable to use at least one selected from the group consisting of silica, alumina, titanium oxide, and boron nitride, and it is more preferable to use at least one selected from the group consisting of silica, alumina, and boron nitride. Examples of the organic filler include a resin filler (resin particles). Examples of the resin filler include polyurethane and polyimide. When a resin filler is used, flexibility at a high temperature such as 260° C. can be imparted. It is noted that an organic filler formed of a thermoplastic resin does not correspond to the above-described thermoplastic resin.

From the viewpoint of having more excellent insulation reliability, it is preferable that the filler is insulative. It is preferable that the first adhesive does not contain a filler including a conductive material (conductive filler) such as silver, solder, or carbon black.

The physical properties of the filler may be adjusted as appropriate by a surface treatment. From the viewpoint that dispersibility or adhesive power is improved, the filler may be a filler that has been subjected to a surface treatment. Examples of the surface treatment agent include glycidyl-based (epoxy-based), amine-based, phenyl-based, phenylamino-based, (meth)acryl-based, and vinyl-based compounds.

The average particle size of the filler is, for example, 0.5 to 1.5 μm. The average particle size of the filler is preferably 1.5 μm or less from the viewpoint of preventing jamming at the time of flip-chip connection, and is more preferably 1.0 μm or less from the viewpoint of having excellent visibility (transparency). The average particle size of the filler is the particle size at a point corresponding to 50% of the volume when a cumulative frequency distribution curve based on the particle size is determined by taking the total volume of the particles as 100%, and the average particle size can be measured with a particle size distribution analyzer using a laser diffraction scattering method, or the like.

From the viewpoint that the heat dissipation properties are lowered, and from the viewpoint that the generation of voids, an increase in the coefficient of moisture absorption, and the like are easily suppressed, the content of the filler in the first adhesive region 2 is preferably 25% by mass or more, more preferably 30% by mass or more, and even more preferably 35% by mass or more, based on the total amount of the first adhesive. From the viewpoint of suppressing the occurrence of jamming (trapping) of the filler at the connecting parts, the content of the filler is preferably 60% by mass or less, more preferably 55% by mass or less, and even more preferably 50% by mass or less, based on the total amount of the first adhesive.

In a case where the filler includes an inorganic filler and an organic filler, the content of the inorganic filler in the first adhesive region 2 may be 60% by mass or more, 70% by mass or more, or 80% by mass or more, may be 98% by mass or less, 95% by mass or less, or 90% by mass or less, and may be 60 to 98% by mass, 70 to 95% by mass, or 80 to 90% by mass, based on the total amount of the filler in the first adhesive region 2.

The first adhesive region 2 may further contain additives such as an oxidation inhibitor, a silane coupling agent, a titanium coupling agent, a leveling agent, and an ion trapping agent. These can be used singly or in combination of two or more kinds thereof. The contents of these may be adjusted as appropriate so that the effect of each additive is exhibited. The first adhesive region 2 may include a flux compound that will be described below, and the content of the flux compound is preferably less than 0.5% by mass, more preferably less than 0.01% by mass, and even more preferably 0% by mass, based on the total amount of the second adhesive. Particularly, in a case where the first adhesive is radically polymerizable (radical-curable), curing of the first adhesive is likely to be inhibited by the flux compound, and therefore, it is preferable that the first adhesive does not include a flux compound.

The thickness of the first adhesive region 2 (length in the thickness direction of the film-shaped adhesive 1) may be set as appropriate based on the relationship with the height of the connecting parts in the connecting members to which the film-shaped adhesive 1 is stuck before irradiation with light. When the height of the connecting part is designated as y1, and the thickness of the first adhesive region 2 is designated as x1, it is preferable that the relationship between x1 and y 1 satisfies x1<y1, and it is more preferable that the relationship satisfies 1.0x1<y1≤1.5x1, from the viewpoint that it is difficult for a cured product of the first adhesive to intervene between the connecting parts, and the connection reliability n be further improved. Specifically, the thickness of the first adhesive region 2 may be 1 to 50 μm, or may be 3 to 50 μm, 4 to 30 μm, or 5 to 20 μm.

### (Second Adhesive Region)

The second adhesive region 3 contains, for example, a thermosetting resin, a thermal curing agent, and a flux compound.

As the thermosetting resin and the thermal curing agent, the same ones as those mentioned as examples of the thermosetting resin and the thermal curing agent contained in the first adhesive region 2 can be used. Preferred examples of the thermosetting resin and the thermal curing agent are also the same as those in the case of the first adhesive region 2. The thermosetting resin and the thermal curing agent in the first adhesive region 2 and the thermosetting resin and the thermal curing agent in the second adhesive region 3 may be the same or may be different.

From the viewpoint of allowing the generation of fillet to be easily suppressed, the content of the thermosetting resin in the second adhesive region 3 is preferably 25% by mass or more, more preferably 30% by mass or more, and even more preferably 35% by mass or more, based on the total amount of the second adhesive. From the viewpoint that satisfactory sealing properties and adhesiveness are likely to be obtained, the content of the thermosetting resin is preferably 50% by mass or less, more preferably 45% by mass or less, and even more preferably 40% by mass or less, based on the total amount of the second adhesive.

From the viewpoint that curability at the time of heating is improved, the content of the thermal curing agent in the second adhesive region 3 is preferably 1 part by mass or more, more preferably 2 parts by mass or more, and even more preferably 3 parts by mass or more, with respect to 100 parts by mass of the thermosetting resin. From the viewpoint that it can be made more difficult for the intervention of the second adhesive between the connecting parts to occur, the content of the thermal curing agent is preferably 10 parts by mass or less, more preferably 7 parts by mass or less, and even more preferably 5 parts by mass or less, with respect to 100 parts by mass of the thermosetting resin. Incidentally, the thermosetting resin is the thermosetting resin in the second adhesive region 3.

### [Flux Compound]

The flux compound is a compound having flux activity. As the flux compound, any known flux compound can be used without particular limitation as long as it reduces and removes an oxide film on the surface of solder or the like and facilitates metal joining. Regarding the flux compound, one kind thereof may be used alone, or two or more kinds thereof may be used in combination.

From the viewpoint of obtaining sufficient flux activity and obtaining excellent connection reliability, it is preferable that the flux compound has a carboxy group, it is more preferable that the flux compound has two or more carboxy groups, and it is even more preferable that the flux compound has two carboxy groups. A compound having two or more carboxy groups is less likely to be volatilized by the high temperature at the time of connection, as compared with a compound having one carboxy group (monocarboxylic acid). Accordingly, when the compound is used, the generation of voids can be further suppressed. In addition, a compound having two carboxy groups has an excellent effect of suppressing the viscosity increase of the film-shaped adhesive 1 during storage, during a connection operation, and the like, as compared with a compound having three or more carboxy groups.

As the flux compound having a carboxy group, a compound having a group represented by the following Formula (1) is preferably used.

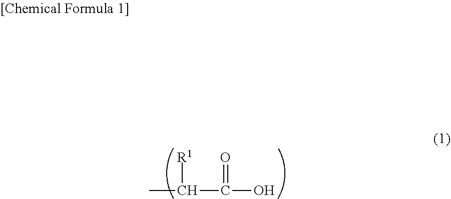

In Formula (1), R¹ represents a hydrogen atom or an electron-donating group.

From the viewpoint of having excellent reflow resistance and from the viewpoint of having more excellent connection reliability, it is preferable that R¹ is electron-donating. In the present embodiment, it is more preferable that the second adhesive contains an epoxy resin and then further contains a compound in which R¹ is an electron-donating group among those compounds having a group represented by Formula (1). In this case, even for the flip-chip connection system, the production of a semiconductor device that is more excellent in terms of reflow resistance and connection reliability, is facilitated.

Examples of the electron-donating group include an alkyl group, a hydroxyl group, an amino group, an alkoxy group, and an alkylamino group. As the electron-donating group, a group that is less likely to react with other components (for example, an epoxy resin) is preferred, and specifically, an alkyl group, a hydroxyl group, or an alkoxy group is preferred, while an alkyl group is more preferred.

The alkyl group may be linear or branched; however, it is preferable that the alkyl group is linear. Regarding the alkyl group, an alkyl group having 1 to 10 carbon atoms is preferred, and an alkyl group having 1 to 5 carbon atoms is more preferred. As the number of carbon atoms in an alkyl group is larger, the electron-donating properties and steric hindrance tend to be increased. An alkyl group whose number of carbon atoms is in the above-described range has excellent balance between electron-donating properties and steric hindrance.

As the flux compound having two carboxy groups, a compound represented by the following Formula (2) can be suitably used. When a compound represented by the following Formula (2) is used, the reflow resistance and connection reliability of the semiconductor device can be further improved.

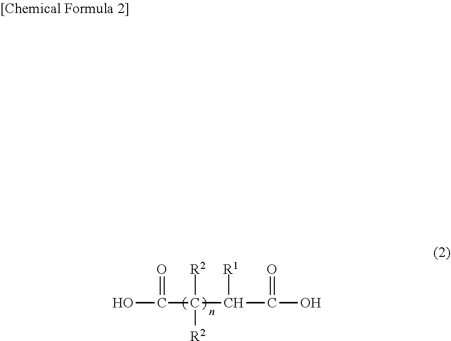

In Formula (2), R¹ has the same meaning as that in Formula (1). R² represents a hydrogen atom or an electron-donating group, and n represents an integer of 0 or 1 or greater.

The electron-donating properties exhibited by R² are the same as the examples of the above-mentioned electron-donating group described as R¹. R² may be the same as or different from R¹. A plurality of R² present in the compound may be identical with or different from each other.

n in Formula (2) is preferably 1 or greater. When n is 1 or greater, the flux compound is less likely to be volatilized even at the high temperature at the time of connection, and the generation of voids can be further suppressed, as compared with the case where n is 0. In addition, n in Formula (2) is preferably 15 or less, and more preferably 11 or less, and may be 6 or less or 4 or less. When n is 15 or less, more excellent connection reliability is obtained.

Specific examples of the flux compound such as described above include dicarboxylic acids such as succinic acid, glutaric acid, adipic acid, pimelic acid, suberic acid, azelaic acid, sebacic acid, undecanedioic acid, and dodecanedioic acid; and compounds obtained by substituting an electron-donating group at the 2-position of these dicarboxylic acids (for example, 2-methylglutaric acid).

The melting point of the flux compound is preferably 150° C. or lower, more preferably 140° C. or lower, and even more preferably 130° C. or lower. Such a flux compound is likely to sufficiently exhibit flux activity before a curing reaction between an epoxy resin and a curing agent occurs. Accordingly, a semiconductor device having more excellent connection reliability can be obtained by using such a flux compound. It is preferable that the flux compound is solid at room temperature (25° C.). The melting point of the flux compound is preferably 25° C. or higher, and more preferably 50° C. or higher. In the present specification, a melting point of 150° C. or lower means that the upper limit point of the melting point is 150° C. or lower, and a melting point of 25° C. or higher means that the lower limit point of the melting point is 25° C. or higher.

From the viewpoint that a flux effect is obtained more satisfactorily, the content of the flux compound in the second adhesive region 3 is preferably 0.1% by mass or more, more preferably 0.3% by mass or more, and even more preferably 0.5% by mass or more, based on the total amount of the second adhesive. From the viewpoint of reducing the amount of warpage in the wafer at the time of producing a semiconductor device, the content of the flux compound is preferably 5% by mass or less, more preferably 3% by mass or less, and even more preferably 2% by mass or less, based on the total amount of the second adhesive.

The second adhesive region 3 may further include a filler, a thermoplastic resin, and the like, similarly to the first adhesive region 2. Regarding these, the same ones as those mentioned as examples of the agents that may be contained in the first adhesive region 2, can be used. Preferred examples of these are also the same as those in the case of the first adhesive region 2. The filler in the first adhesive region 2 and the filler in the second adhesive region 3 may be the same or may be different. The same also applies to the thermoplastic resin.

From the viewpoint that the heat resistance and film-forming properties of the second adhesive are likely to be improved, the content of the thermoplastic resin in the second adhesive region 3 is preferably 5% by mass or more, more preferably 7% by mass or more, and even more preferably 10% by mass or more, based on the total amount of the second adhesive. From the viewpoint of allowing the generation of fillet to be easily suppressed, the content of the thermoplastic resin is preferably 30% by mass or less, more preferably 25% by mass or less, and even more preferably 20% by mass or less, based on the total amount of the second adhesive.

From the viewpoint that a decrease in the heat dissipation properties is suppressed, and from the viewpoint that the generation of voids, an increase in the coefficient of moisture absorption, and the like are easily suppressed, the content of the filler in the second adhesive region 3 is preferably 25% by mass or more, more preferably 30% by mass or more, and even more preferably 35% by mass or more, based on the total amount of the second adhesive. From the viewpoint of suppressing the occurrence of jamming (trapping) of the filler to the connecting parts, the content of the filler is preferably 60% by mass or less, more preferably 55% by mass or less, and even more preferably 50% by mass or less, based on the total amount of the second adhesive.

The second adhesive region 3 may further include the additives mentioned as examples of the additives that may be included in the first adhesive region 2. The contents of these may be adjusted as appropriate so that the effect of each additive is exhibited.

The second adhesive region 3 does not contain a combination of a photopolymerizable compound and a photopolymerization initiator. In a case where a photopolymerization initiator is not used, the second adhesive region 3 may include a compound that may be included as a photopolymerizable compound in the above-described first adhesive region 2. However, from the viewpoint of preventing a reaction with an active species generated when the first adhesive region 2 is cured, it is preferable that the second adhesive region 3 does not include a compound that is polymerized by an active species generated by the photopolymerization initiator that is included in the first adhesive region. The content of the compound that is polymerized by the active species generated by the above-described photopolymerization initiator is preferably 0.5% by mass or less, more preferably 0.05% by mass or less, and even more preferably 0% by mass, based on the total amount of the second adhesive.

As described above, from the viewpoint that there are some flux compounds that deactivate radicals among flux compounds, and that the presence of a radically polymerizable compound causes the curing reaction to proceed rapidly during heating, and the cured product is likely to intervene between the connecting parts, it is preferable that the second adhesive region 3 does not contain a radically polymerizable compound. The content of the radically polymerizable compound is preferably 0.5% by mass or less, more preferably 0.05% by mass or less, and even more preferably 0% by mass, based on the total amount of the second adhesive. The thickness of the second adhesive region (length in the thickness direction of the film-shaped adhesive 1) may be 1 to 50 μm or may be 3 to 50 μm, 4 to 30 μm, or 5 to 20 μm.

The thickness of the second adhesive region 3 may be 0.5 to 2 times the thickness of the first adhesive region 2, and may be 0.5 to 2.5 times, or 0.5 to 3 times.

The thickness of the film-shaped adhesive 1 (for example, sum of the thickness of the first adhesive region 2 and the thickness of the second adhesive region 3) may be appropriately set in relation to the connecting parts of the connecting members. When the sum of heights of the connecting parts is designated as x, and the total thickness of the film-shaped adhesive is designated as y, it is preferable that 0.70x≤y≤1.3x is satisfied, and it is more preferable that 0.80x≤y≤1.2x is satisfied, from the viewpoints of the connectivity at the time of pressure-bonding and the filling properties of the adhesive. From the viewpoint that it is difficult for the cured product of the first adhesive to intervene between the connecting parts, and the connection reliability is further improved, it is preferable that y>x is satisfied. Specifically, the thickness of the film-shaped adhesive 1 may be 2 to 100 μm, or may be 6 to 100 μm, 8 to 60 μm, or 10 to 40 μm.

The film-shaped adhesive 1 may include a base material such as a support film or a protective film on the surface on the first adhesive region 2 side (opposite side of the second adhesive region 3), and/or on the surface of the second adhesive region 3 side (opposite side of the first adhesive region 2). In the present disclosure, a laminated body including a base material and a film-shaped adhesive provided on the base material is referred to as adhesive tape.

As the base material, base materials that will be mentioned as examples of a base material used in the method for producing a film-shaped adhesive, which will be described below, can be used; however, the base material that is provided on the second adhesive region 3 side of the film-shaped adhesive 1 is preferably a back grinding tape. A back grinding tape is usually configured such that one principal surface side is a tacky adhesive layer; however, in this case, the back grinding tape is provided on the film-shaped adhesive 1 such that the surface on the tacky adhesive layer side comes on the film-shaped adhesive 1 side (for example, such that the tacky adhesive layer and the film-shaped adhesive are in contact). The thickness of the base material 4 (for example, thickness of the back grinding tape) may be 20 to 300 μm.

The adhesive tape may be a laminated body of a base material and a film-shaped adhesive obtained by the method for producing a film-shaped adhesive that will be described below, that is, a method of applying a coating liquid on a base material, forming a coating film, and drying the coating film, or the adhesive tape may be a laminated body obtained by sticking a base material to the film-shaped adhesive 1 (for example, laminating the film-shaped adhesive 1 and a base material). In a case where the base material is a back grinding tape, when application and drying of a coating liquid are performed on the tacky adhesive layer of the back grinding tape, there is a possibility that problems such as destruction of the adhesive layer and migration of components between the tacky adhesive and the adhesive may occur, and therefore, it is preferable to obtain an adhesive tape by sticking a back grinding tape to the film-shaped adhesive 1.

### <Method for Producing Film-Shaped Adhesive for Semiconductors>

An embodiment of a method for producing the film-shaped adhesive 1 includes a step of providing any one of a first adhesive layer having photocurability and thermosetting properties and a second adhesive layer having thermosetting properties but not having photocurability, on the other. Here, the first adhesive layer is a layer composed of the above-described first adhesive and forms a first adhesive region 2 in the film-shaped adhesive 1. The second adhesive layer is a layer composed of the above-described second adhesive and forms a second adhesive region 3 in the film-shaped adhesive 1.

According to an embodiment, the above-described step may be, for example, a step of sticking together a first adhesive film including the above-described first adhesive layer, and a second adhesive film including the above-described second adhesive layer. In this embodiment, the method for producing the film-shaped adhesive 1 may further include a step of preparing the above-described first adhesive film and the above-described second adhesive film.

The step of preparing the first adhesive film may include forming the first adhesive layer on a base material (for example, a film-shaped base material). In the case of forming the first adhesive layer on a base material, for example, first, a photopolymerizable compound, a photopolymerization initiator, a thermosetting resin, and a thermal curing agent, and other components that are added as needed (filler, a thermoplastic resin, additives, and the like) are added into an organic solvent, and the components are dissolved or dispersed by stirred mixing, kneading, or the like to prepare a coating liquid including a first adhesive. Thereafter, the coating liquid is applied on a base material that has been subjected to a mold release treatment, by using a knife coater, a roll coater, an applicator, or the like to form a coating film, and then the organic solvent is reduced from the coating film by heating. As a result, a first adhesive layer can be formed on the base material.

Regarding the organic solvent used for preparing the coating liquid, an organic solvent having characteristics that can uniformly dissolve or disperse each component is preferred, and examples thereof include dimethylformamide, dimethylacetamide, N-methyl-2-pyrrolidone, dimethyl sulfoxide, diethylene glycol dimethyl ether, toluene, benzene, xylene, methyl ethyl ketone, tetrahydrofuran, ethyl cellosolve, ethyl cellosolve acetate, butyl cellosolve, dioxane, cyclohexanone, and ethyl acetate. These organic solvents can be used singly or in combination of two or more kinds thereof. Stirred mixing and kneading at the time of preparing the coating liquid can be performed by, for example, using a stirrer, a Raikai mixer, a three-roll, a ball mill, a bead mill, or a Homodisper.

The base material is not particularly limited as long as it has heat resistance that can withstand the heating conditions at the time of volatilizing the organic solvent, and examples thereof include polyolefin films such as a polypropylene film and a polymethylpentene film; polyester films such as a polyethylene terephthalate film and a polyethylene naphthalate film; a polyimide film; and a polyetherimide film. The base material is not limited to a single layer base material formed from any of these films, and may be a multilayer film formed from two or more kinds of materials. The base material may also be a film subjected to a mold release treatment on the surface.

The drying conditions at the time of volatilizing the organic solvent from the coating film on the base material are preferably conditions in which the organic solvent is sufficiently volatilized, and specifically, it is preferable to perform heating at 50 to 200° C. for 0.1 to 90 minutes. Unless the voids or viscosity adjustment after mounting is affected, it is preferable that the organic solvent is removed to a level of 1.5% by mass or less with respect to the total amount of the first adhesive.

The step of preparing the second adhesive film may include forming the second adhesive layer on the base material. The second adhesive layer can be formed on the base material by a method similar to the method for forming the first adhesive layer, except that a thermosetting resin, a thermal curing agent, a flux compound, and other components that are added as needed (a filler, a thermoplastic resin, additives, and the like) are used.

Regarding the method of sticking the first adhesive film and the second adhesive film together, for example, methods of hot pressing, roll lamination, vacuum lamination, and the like may be mentioned. Lamination may be performed, for example, under heating conditions at 30 to 120° C.

The film-shaped adhesive 1 may be obtained by, for example, forming one of the first adhesive layer and the second adhesive layer on the base material and then forming the other of the first adhesive layer and the second adhesive layer on the obtained first adhesive layer or second adhesive layer. The first adhesive layer and the second adhesive layer can be formed by the above-described methods.

The film-shaped adhesive 1 may also be obtained by, for example, forming the first adhesive and the second adhesive on the base material substantially at the same time. Examples of a method for producing the first adhesive and the second adhesive by simultaneous coating include coating methods such as a sequential coating method and a multilayer coating method.

### <Semiconductor Device>

Next, a semiconductor device produced by using the film-shaped adhesive for semiconductors of the above-described embodiments will be described.

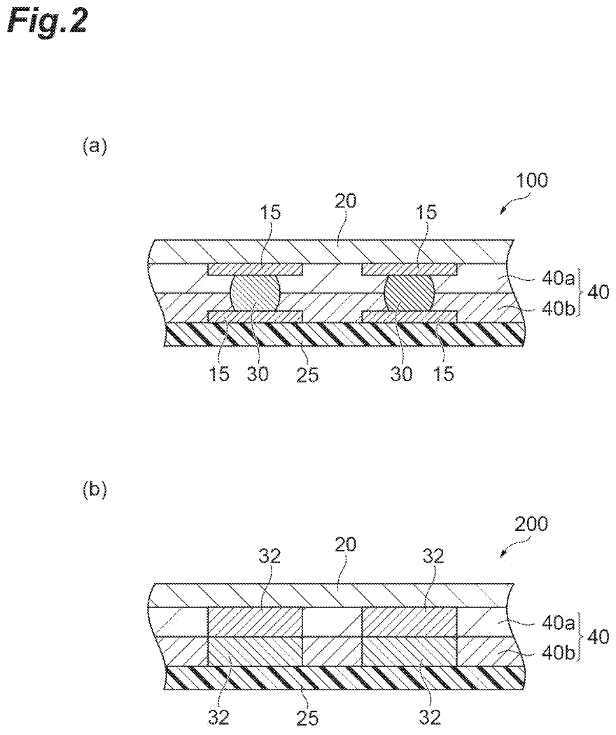

FIG. 2 is a schematic cross-sectional view illustrating an embodiment of the semiconductor device. A semiconductor device 100 shown in FIG. 2(a) includes: a semiconductor chip 20 and a base 25 facing each other; wiring lines (first connecting part and second connecting part) 15 respectively disposed on surfaces of the semiconductor chip 20 and the base 25, the surfaces facing each other; connecting bumps 30 connecting the wiring lines 15 of the semiconductor chip 20 and the base 25 to each other; and a sealing part 40 formed of cured products of the adhesives (first adhesive and second adhesive) that fill the gap between the semiconductor chip 20 and the base 25. The semiconductor chip 20 and the base 25 are flip-chip connected by the wiring lines 15 and the connecting bumps 30. The wiring lines 15 and the connecting bumps 30 are sealed by cured products of the adhesives and are isolated from the external environment. The sealing part 40 has an upper portion 40a including a cured product of the first adhesive, and a lower portion 40b including a cured product of the second adhesive.

A semiconductor device 200 shown in FIG. 2(b) includes: a semiconductor chip 20 and a base 25 facing each other; bumps (first connecting part and second connecting part) 32 respectively disposed on surfaces of the semiconductor chip 20 and the base 25, the surfaces facing each other; and a sealing part 40 formed of cured products of the adhesives (first adhesive and second adhesive) that fill the gap between the semiconductor chip 20 and the base 25. The semiconductor chip 20 and the base 25 are flip-chip connected as bumps 32 facing each other are connected to each other. The bumps 32 are sealed by cured products of the adhesives and are isolated from the external environment. The sealing part 40 has an upper portion 40a including a cured product of the first adhesive, and a lower portion 40b including a cured product of the second adhesive.

The semiconductor chip 20 is not particularly limited, and a semiconductor chip formed of an elemental semiconductor composed of the same type of elements such as silicon or germanium, or a semiconductor chip formed of a compound semiconductor such as gallium arsenide or indium phosphide, can be used.

The base 25 is not particularly limited as long as it is used for loading the semiconductor chip 20, and examples thereof include a semiconductor chip, a semiconductor wafer, and a wiring circuit board.

Examples of the semiconductor chip that can be used as the base 25 are the same as the examples of the above-described semiconductor chip 20, and the same semiconductor chip as the semiconductor chip 20 may be used as the base 25.

The semiconductor wafer that can be used as the base 25 is not particularly limited, and a semiconductor wafer having a configuration in which a plurality of the semiconductor chips mentioned as examples of the above-described semiconductor chip 20 are linked may be used.

The wiring circuit board that can be used as the base 25 is not particularly limited, and a circuit board having wiring lines (wiring pattern) 15 formed on the surface of an insulating substrate containing glass epoxy, polyimide, polyester, ceramic, bismaleimide triazine, or the like as a main component by removing unnecessary parts of a metal film by etching; a circuit board having wiring lines 15 formed on the surface of the above-described insulating substrate by metal plating or the like; a circuit board having wiring lines 15 formed on the surface of the above-described insulating substrate by printing a conductive substance; or the like can be used.

The connecting parts such as wiring lines 15 and bumps 32 contain gold, silver, copper, solder (main components are, for example, tin-silver, tin-lead, tin-bismuth, tin-copper, and tin-silver-copper), nickel, tin, lead, or the like as a main component, and may contain a plurality of metals.

Among the above-described metals, from the viewpoint of providing a package in which the connecting parts have excellent electrical conductivity and thermal conductivity, gold, silver, and copper are preferable, and silver and copper are more preferable. From the viewpoint of providing a package at reduced cost, silver, copper, and solder, which are inexpensive materials, are preferable, copper and solder are more preferable, and solder is even more preferable. When an oxide film is formed on the surface of metal at room temperature, productivity may decrease while cost may increase, and therefore, from the viewpoint of suppressing the formation of an oxide film, gold, silver, copper, and solder are preferable, gold, silver, and solder are more preferable, and gold and silver are even more preferable.

On the surface of the above-described wiring lines 15 and bumps 32, a metal layer containing gold, silver, copper, solder (main components are, for example, tin-silver, tin-lead, tin-bismuth, and tin-copper), tin, nickel, or the lime as a main component, may be formed by, for example, plating. This metal layer may be composed only of a single component or may be composed of a plurality of components. In addition, the above-described metal layer may have a single layer structure or a structure in which a single layer or a plurality of metal layers are stacked.

The semiconductor device may be such that a plurality of structures (packages) as shown in the semiconductor devices 100 and 200 are stacked. In this case, the semiconductor devices 100 and 200 may be electrically connected to each other by means of bumps, wiring lines, and the like, which include gold, silver, copper, solder (main components are, for example, tin-silver, tin-lead, tin-bismuth, tin-copper, and tin-silver-copper), tin, nickel, or the like.

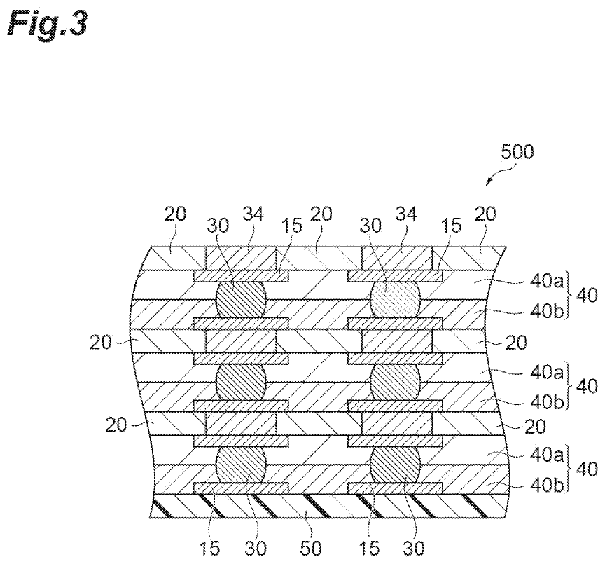

Regarding a technique of stacking a plurality of semiconductor devices, as shown in FIG. 3, for example, a TSV (Through-Silicon Via) technology may be mentioned. In a semiconductor device 500 shown in FIG. 3, as wiring lines 15 formed on an interposer 50 are connected to wiring lines 15 of a semiconductor chip 20 through connecting bumps 30, the semiconductor chip 20 and the interposer 50 are flip-chip connected. A gap between the semiconductor chip 20 and the interposer 50 is filled with cured products of adhesives (first adhesive and second adhesive), and the cured products constitute a sealing part 40. On the surface on the opposite side of the interposer 50 in the above-described semiconductor chip 20, semiconductor chips 20 are repeatedly stacked, with wiring lines 15, connecting bumps 30, and sealing parts 40 interposed therebetween. The wiring lines 15 of the patterned surfaces on the front and back sides of the semiconductor chip 20 are connected to each other by through electrodes 34 filling in the holes penetrating through the inside of the semiconductor chip 20. As the material of the through electrode 34, copper, aluminum, and the like can be used.

It is made possible by such a TSV technology to acquire signals even from the back side of the semiconductor chip, which is normally not used. In addition, since the through electrodes 34 vertically pass through the semiconductor chips 20, the distance between semiconductor chips 20 facing each other, and the distance between a semiconductor chip 20 and an interposer 50 can be shortened, and flexible connection is enabled. The film-shaped adhesive for semiconductors of the present embodiment can be applied as a film-shaped adhesive for semiconductors between semiconductor chips 20 facing each other and between a semiconductor chip 20 and an interposer 50 in such a TSV technology.

Furthermore, in bump forming methods with a high degree of freedom, such as an area bump chip technology, semiconductor chips can be directly mounted as they are on a motherboard without using interposers. The film-shaped adhesive for semiconductors of the present embodiment can be applied even in a case where such semiconductor chips are mounted directly on a motherboard. The film-shaped adhesive for semiconductors of the present embodiment can also be applied when sealing gaps (voids) between substrates in a case where two wiring circuit substrates are stacked.

### <Method for Producing Semiconductor Device>

Next, a method for producing a semiconductor device using the film-shaped adhesive for semiconductors of the above-described embodiments will be described.

The method for producing a semiconductor device according to an embodiment includes, for example, a light irradiation step of irradiating a first adhesive region 2 of a film-shaped adhesive 1 with light; and a step of heating and joining a semiconductor chip and a base in a state in which the semiconductor chip and the base are arranged such that the connecting parts thereof face each other, with the film-shaped adhesive for semiconductors after light irradiation interposed therebetween. The above-described light irradiation step is carried out in a state in which the film-shaped adhesive 1 is stuck, from the side of the first adhesive region 2, to a connecting surface of the semiconductor chip or a precursor thereof, or a connecting surface of the base or a precursor thereof. Here, the precursor of the semiconductor chip means a member that becomes a semiconductor chip through processing. A specific example of the precursor of the semiconductor chip is a semiconductor wafer. The same also applies to the precursor of the base.

The method for producing a semiconductor device may further include: a step of preparing an adhesive tape including a film-shaped adhesive for semiconductors and a back grinding tape provided on the film-shaped adhesive for semiconductors, on the opposite side of the first adhesive region side as viewed from the second adhesive region; a lamination step of sticking the adhesive tape, from the side of the film-shape adhesive for semiconductors, to a connecting surface of a precursor of a semiconductor chip or a precursor of a base; and a back grinding step of grinding the precursor to which the adhesive tape is stuck, from the opposite side of the adhesive tape. The light irradiation in the light irradiation step may be performed to progress through the back grinding tape; however, it is preferable that light irradiation is performed after the back grinding tape is removed after the back grinding step.

In the following description, the method for producing a semiconductor device will be described by taking an embodiment of using a semiconductor wafer as a precursor of a semiconductor chip as an example.

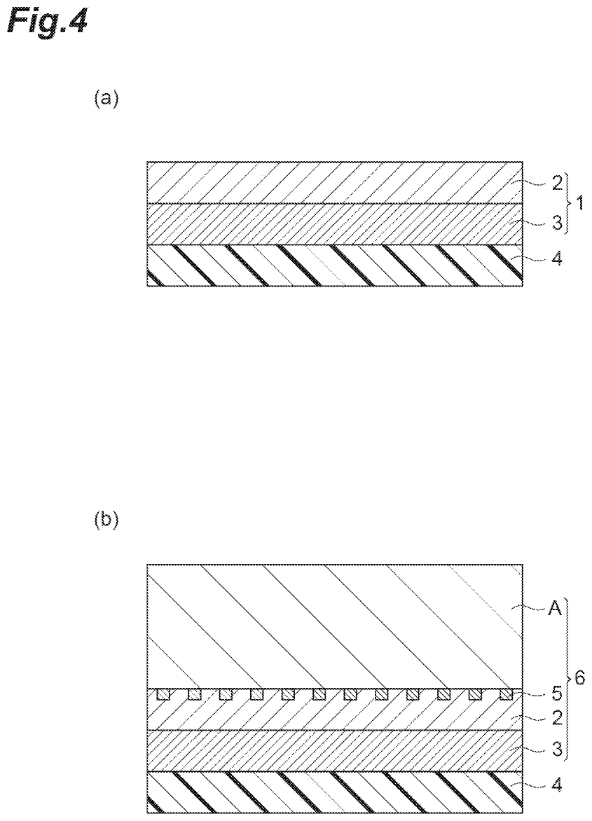

FIG. 4 to FIG. 9 are process cross-sectional views schematically illustrating an embodiment of the method for producing a semiconductor device. The production method of an embodiment includes the following steps (a) to (e).

Step (a): A step of preparing a laminated body 6 including a semiconductor wafer A having a connecting part (first connecting part) 5 on one principal surface (connecting surface), and a film-shaped adhesive 1 provided on the principal surface of the semiconductor wafer A such that a face on the first adhesive region 2 side comes on the semiconductor wafer A side (see FIG. 4).

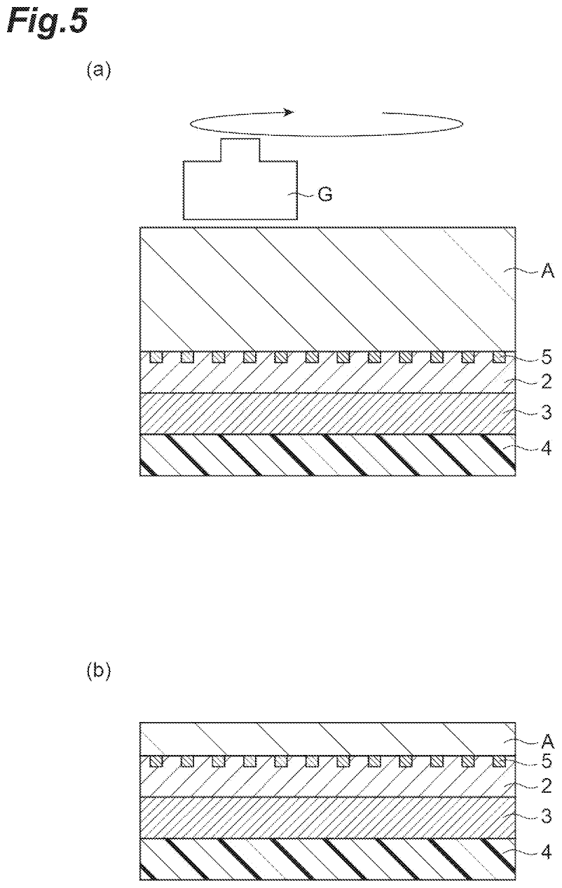

Step (b): A back grinding step of grinding the side of the laminated body 6 opposite from the side where the film-shaped adhesive 1 is provided (opposite side of the side where the connecting part 5 of the semiconductor wafer A is provided) (see FIG. 5).

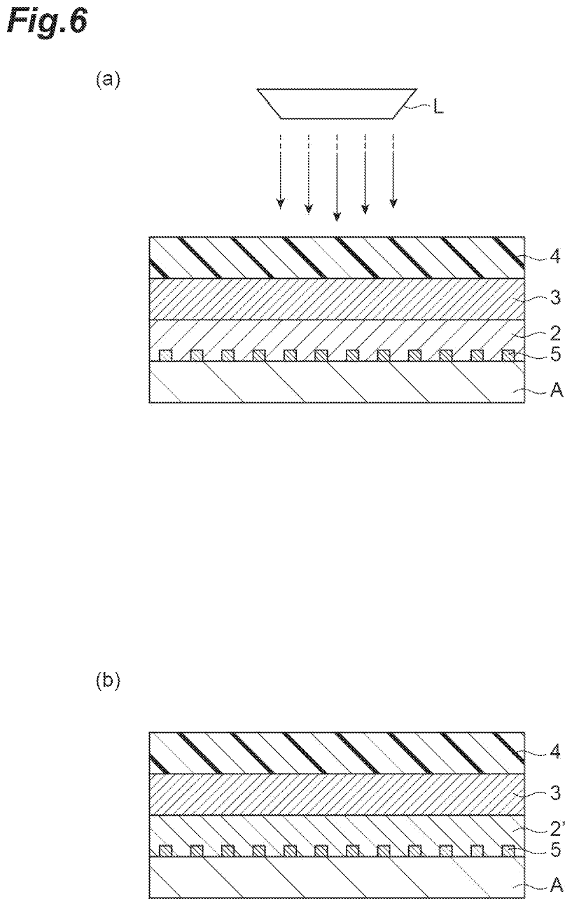

Step (c): A step of irradiating the laminated body 6 after step (b) with light such that the first adhesive region 2 of the film-shaped adhesive 1 is irradiated with light (see FIG. 6).

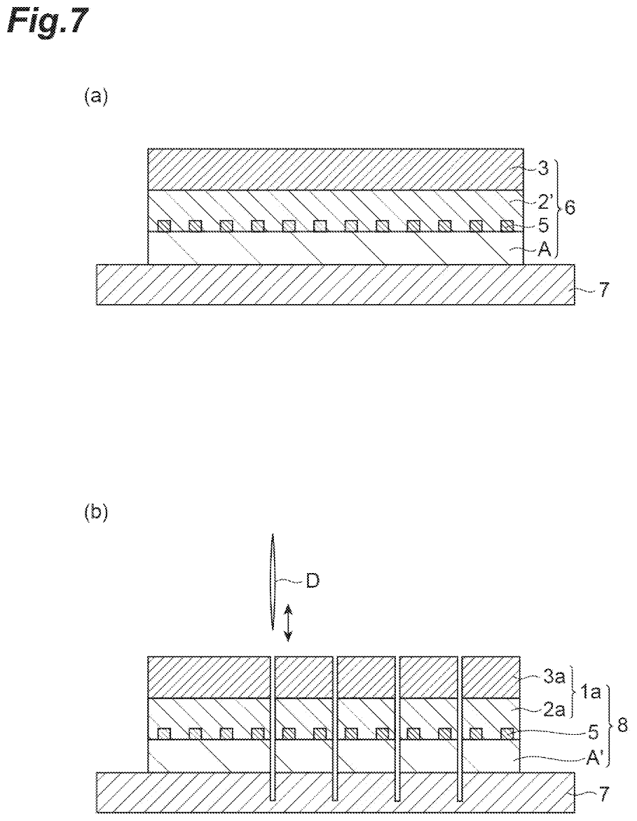

Step (d): A step of singularizing the laminated body 6 after step (b) and obtaining film-shaped adhesive-attached semiconductor chips 8 having the connecting parts 5 (see FIG. 7).

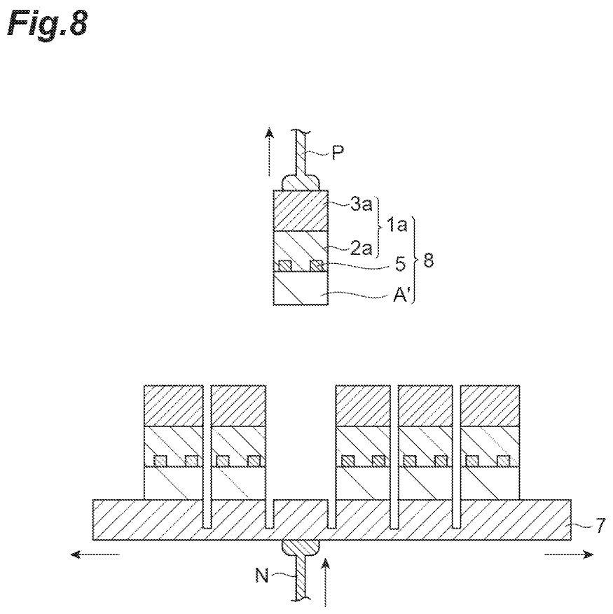

Step (e): A step of picking up the film-shaped adhesive-attached semiconductor chips 8 from the singularized film-shaped adhesive 1a side (see FIG. 8).

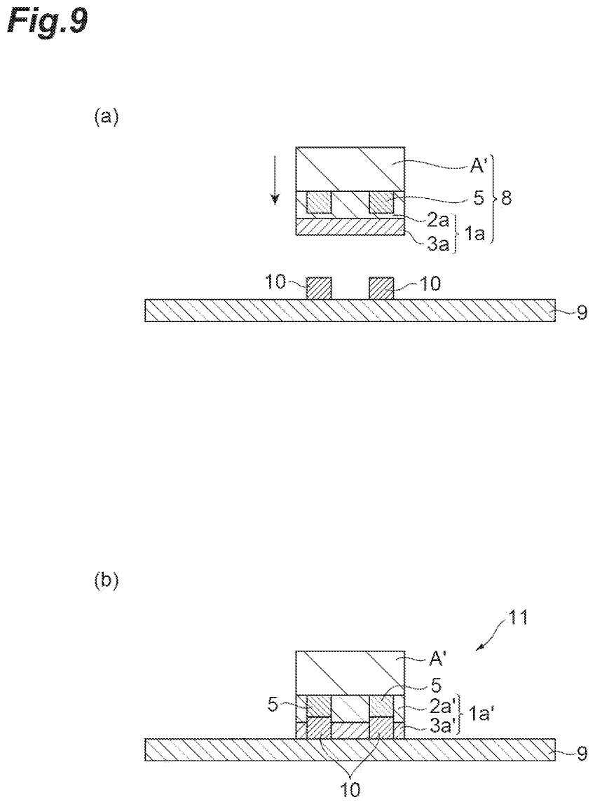

Step (f): A step of disposing a film-shaped adhesive-attached semiconductor chip 8 on one principal surface of a base 9 having a connecting part ((second connecting part) 10 on the principal surface (connecting surface), from the side of the film-shaped adhesive 1a, and heating the film-shaped adhesive-attached semiconductor chip 8 to electrically connect the connecting part 5 of the film-shaped adhesive-attached semiconductor chip 8 and the connecting part 10 of the base 9 (see FIG. 9).

In a case where a semiconductor wafer whose thickness has been adjusted in advance is used, it is not necessary to carry out step (b). Furthermore, step (c) may be carried out before step (f), or may be carried out before step (b) or after step (d).

### (Step (a))

Step (a) may be a step of preparing a laminated body 6 that has been produced in advance, or may be a step of producing a laminated body 6. The laminated body 6 may be produced by, for example, the following method.

First, an adhesive tape in which a base material 4 is provided on the second adhesive region 3 side of the film-shaped adhesive 1, is prepared, and this is placed on a predetermined apparatus (see FIG. 4(a)). The base material 4 is, for example, a back grinding tape. Next, a semiconductor wafer A having a connecting part 5 (wiring lines, bumps, and the like) on one principal surface is prepared, and the film-shaped adhesive 1 is stuck onto the principal surface (surface where the connecting part 5 is provided, connecting surface) of the semiconductor wafer A. As a result, a laminated body 6 in which the semiconductor wafer A, the first adhesive region 2, and the second adhesive region 3 are stacked in this order, is obtained (see FIG. 4(b)).

Sticking of the film-shaped adhesive 1 can be performed by hot pressing, roll lamination, vacuum lamination, or the like. The supply area and thickness of the film-shaped adhesive 1 are set as appropriate depending on the sizes of the semiconductor wafer and the base, the height of the connecting part, and the like. In FIG. 4, the thickness of the film-shaped adhesive 1 is larger than the height of the connecting part 5 of the semiconductor wafer A, and the connecting part 5 is covered by the film-shaped adhesive 1; however, the thickness of the film-shaped adhesive 1 may be smaller than the height of the connecting part 5.

### (Step (b))

In step (b), for example, the semiconductor wafer A of the laminated body 6 is ground by using a grinder G (see FIG. 5(a) and FIG. 5(b)). As a result, the semiconductor wafer A is thinned. The thickness of the semiconductor wafer after grinding may be, for example, 10 μm to 300 μm. From the viewpoints of size reduction and thickness reduction of semiconductor devices, it is preferable to set the thickness of the semiconductor wafer to 20 μm to 100 μm.

### (Step (c))

In step (c), the first adhesive region 2 is photocured by irradiating the laminated body 6 with light (see FIG. 6(a) and FIG. 6(b)). In FIG. 6(b), the first adhesive region after photocuring is denoted by reference numeral “2′”. Irradiation with light can be performed by, for example, irradiating irradiation light having a wavelength in the range of 150 to 750 nm (for example, ultraviolet light) from a light source L disposed on the film-shaped adhesive 1 side. As the light source L, for example, a low-pressure mercury lamp, a medium-pressure mercury lamp, a high-pressure mercury lamp, an ultrahigh-pressure mercury lamp, a xenon lamp, a metal halide lamp, or an LED light source can be used. The amount of light irradiated can be adjusted as appropriate, and for example, the amount as a cumulative amount of light having a wavelength of 365 nm may be 100 mJ/cm² or more, may be 200 mJ/cm² or more, or may be 300 mJ/cm² or more. The amount of light irradiated may be, for example, 1000 mJ/cm² or less, may be 700 mJ/cm² or less, or may be 500 mJ/cm² or less, as a cumulative amount of light having a wavelength of 365 nm. As shown in FIG. 6, in a case where the base material 4 is transparent, irradiation of light may be performed in a state in which the base material 4 is stuck to the laminated body 6, or irradiation of light may be performed after the base material 4 is peeled off. In a case where the base material 4 is a material that is peeled off when irradiated with light, the step (c) may combine a step for peeling off the base material 4.

### (Step (d))

In step (d), for example, first, a dicing tape 7 is stuck to the semiconductor wafer A side of the laminated body 6, and this is placed on a predetermined apparatus (see FIG. 7(a)). In a case where the step (c) is carried out in a state in which the base material 4 is stuck to the laminated body 6, the base material 4 may be peeled off before sticking or after sticking of the laminated body 6 to the dicing tape 7. Next, the laminated body 6 is diced by using a dicing saw D. In this way, the laminated body 6 is singularized, and film-shaped adhesive-attached semiconductor chips 8 each including the film-shaped adhesive 1a on the semiconductor chip A′ are obtained (see FIG. 7(b)). On the face of the film-shaped adhesive 1a side of the semiconductor chip A′, a connecting part 5 is provided. The film-shaped adhesive 1a has a first adhesive region after photocuring (region formed from a photocuring product of the first adhesive) 2a and a second adhesive region (region formed from the second adhesive) 3a.

### (Step (e))

In step (e), for example, while the film-shaped adhesive-attached semiconductor chips 8 obtained by the above-described dicing are separated apart from each other by expanding (expanding) the dicing tape 7, the film-shaped adhesive-attached semiconductor chips 8 pushed up by a needle N from the dicing tape 7 side are picked up by a pick-up tool P from the film-shaped adhesive 1a side (see FIG. 8). The film-shaped adhesive-attached semiconductor chips 8 thus picked up are delivered to a bonding tool to be used for bonding in step (f).

### (Step (f))

In step (f), for example, first, a base 9 for loading semiconductor chips, which has a connecting part 12 (second connecting part) on one surface, is prepared, and alignment of a film-shaped adhesive-attached semiconductor chip 8 and the base 9 is performed. Next, the film-shaped adhesive-attached semiconductor chip 8 is disposed, from the side of the film-shaped adhesive 1a, on the principal surface of the base 9 where the connecting part 10 (wiring lines, bumps, or the like) is provided, by using the bonding tool and heated, and thereby the film-shaped adhesive-attached semiconductor chip 8 and the base 9 are joined (see FIG. 9(a) and FIG. 9(b)). As a result, the connecting part 5 of the film-shaped adhesive-attached semiconductor chip 8 and the connecting part 10 of the base 9 are electrically connected, while at the same time, a sealing part 1a′ formed of a cured product of the film-shaped adhesive 1a is formed between the semiconductor chip A′ and the base 9, the connecting part 5 and the connecting part 10 are sealed, and a semiconductor device 11, which is a joined body of the film-shaped adhesive-attached semiconductor chip 8 and the base 9, is obtained. The sealing part 1a′ has an upper portion 2a′ including a cured product of the first adhesive, and a lower portion 3a′ including a cured product of the second adhesive.

In a case where solder bumps are used for one of the connecting part 5 and the connecting part 10 (for example, in a case where the connecting part 5 or the connecting part 10 is wiring lines provided with solder bumps), the connecting part 5 and the connecting part 10 are electrically and mechanically connected by solder joining.

Heating in the step (f) may be performed while a semiconductor chip is disposed, or may be performed after a semiconductor chip is disposed. The heating and disposition in the step (f) may be thermocompression bonding. The step (f) may include a step of temporarily fixing after performing alignment (temporary fixing step) and a step of melting the bumps (for example, solder bumps) provided at the connecting part by performing a heating treatment to join the semiconductor chip A′ and the base 9, and at the same time, sealing the connecting parts (sealing step). In the stage of temporary fixing, since it is not necessarily essential to form metal joining, the temporary fixing step can be carried out under a small load at a low temperature for a short time. Therefore, in a case where a temporary fixing step and a sealing step are carried out in the step (f), productivity can be improved, and at the same time, deterioration of the connecting parts can be suppressed.

The load to be applied for temporary fixing is set as appropriate in consideration of the control of the number of connecting parts (bumps), the absorption of height variations in the connecting parts (bumps), the amount of deformation of the connecting parts (bumps), and the like. A larger load is more preferable, from the viewpoint of eliminating voids and making it easier to bring the connecting parts into contact. The load is, for example, preferably 0.009 N to 0.2 N per one connecting part (for example, a bump).

The heating in the sealing step may be carried out by using an apparatus capable of heating to a temperature equal to or higher than the melting point of the metal of the connecting parts. The heating temperature is preferably a temperature at which curing of the film-shaped adhesive, and more preferably a temperature at which the film-shaped adhesive is completely cured. The heating temperature and the heating time are set as appropriate.

The heating time in the sealing step varies depending on the type of the metal constituting the connecting parts; however, from the viewpoint that productivity is improved, it is more preferable that the heating time is shorter. In a case where solder bumps are used for the connecting parts, the heating time is preferably 20 seconds or less, more preferably 10 seconds or less, and even more preferably 5 seconds or less. In the case of metal connection of copper-copper or copper-gold, the connection time is preferably 60 seconds or less.

In the sealing step, heating and pressurization may be performed together by using an apparatus capable of heating and pressurization. That is, the heating in the sealing step may be heating by thermocompression bonding. In this case, the load (connection load) is set in consideration of the size of the connecting member, the number of the connecting parts, the variation in the height, the amount of deformation of the connecting parts by pressurization, and the like. The connection load may be, for example, greater than the atmospheric pressure and 1 MPa or less. From the viewpoints of void suppression and improvement in connectivity, a larger load is more preferable, and from the viewpoint of suppressing fillet, a smaller load is more preferable. From these viewpoints, the load is preferably 0.05 to 0.5 MPa. The pressure-bonding time (connection time) may vary depending on the type of the metal forming the connecting parts; however, from the viewpoint of improving productivity, it is more preferable that the pressure-bonding time is shorter. In a case where the connecting parts are solder bumps, the pressure-bonding time is preferably 20 seconds or less, more preferably 10 seconds or less, and even more preferably 5 seconds or less. In the direct pressurization using a pressure-bonding machine, since it is difficult for the heat of the pressure-bonding machine to be transferred to fillet, from the viewpoint of easily applying sufficient effect to the fillet, pressurization by atmospheric pressure is preferred. Even from the viewpoint of batch sealing and suppression of fillet, it is preferable that the pressurization during heating is performed by pressurization by atmospheric pressure (pressurization by a pressure reflow furnace, a pressure oven, or the like).

After the semiconductor chip A′ and the base 9 are connected, a heating treatment may be performed by using an oven or the like to further increase the connection reliability.

### EXAMPLES

Hereinafter, the present disclosure will be described more specifically by way of Examples; however, the present disclosure is not limited to the Examples.

The details of the materials used in the Examples are as follows.

### (Liquid Epoxy Resin)

YX7110B80: Flexible epoxy, manufactured by Mitsubishi Chemical Corporation, trade name “jER YX7110B80”, “jER” is a registered trademark (hereinafter, the same)
YL983U: Bisphenol F type liquid epoxy, manufactured by Mitsubishi Chemical Corporation, trade name “jER YL983U” (solid epoxy resin)
EP1032: Triphenolmethane skeleton-containing polyfunctional solid epoxy, manufactured by Mitsubishi Chemical Corporation, trade name “jER1032H60” (imidazole-based curing agent)
2PHZ-PW: 2-Phenyl-4,5-dihydroxymethylimidazole, manufactured by Shikoku Chemicals Corporation, trade name
2MAOK-PW: 2,4-Diamino-6-[2′-methylimidazolyl-(1′)]-ethyl-s-triazine isocyanuric acid adduct, manufactured by Shikoku Chemicals Corporation, trade name

### (Phenoxy Resin)

ZX-1356-2: Phenoxy resin, manufactured by Tohto Chemical Industry Co., Ltd., trade name, Tg=about 71° C., weight average molecular weight Mw=about 63000

### (Acrylic Compound)

A-DPH: Dipentaerythritol polyacrylate, manufactured by Shin-Nakamura Chemical Co., Ltd., trade name

### (Photopolymerization Initiator)

Omnirad 184:1-Hydroxycyclohexyl phenyl ketone, manufactured by IGM RESINS B.V., trade name (“Omnirad” is a registered trademark; hereinafter, the same)
Omnirad 819: Phenylbis(2,4,6-trimethylbenzoyl)phosphine oxide, manufactured by IGM RESIN B.V., trade name
Omnirad 127:2-Hydroxy-1-(4-(4-(2-hydroxy-2-methylpropionyl)benzyl)phenyl)-2-methylpropan-1-one, manufactured by IGM RESINS B.V., trade name

### (Organic Filler)

EXL-2655: Core-shell type organic microparticles, manufactured by Rohm and Haas Japan KK, trade name

### (Silica Filler)

KE180G-HLA: Silica filler, manufactured by Admatechs Co., Ltd., trade name

### (Flux Compound)

2-Methylglutaric acid: Manufactured by Sigma-Aldrich Corporation, melting point=about 78° C.

### Examples 1 to 7

### (Fabrication of First Adhesive Film)

Among the components shown in Table 1, components other than the photopolymerization initiator were added to an organic solvent (methyl ethyl ketone) such that the NV value ([mass of coating material portion after drying]/[mass of coating material portion before drying]×100) reached 60%, and a mixed liquid was obtained. At this time, the amount of addition of each component was set to the amount (unit: parts by mass) shown in Table 1. Thereafter, beads having a diameter of $1.0 mm and beads having a diameter of $2.0 mm were added to the above-described mixed liquid, and the mixture was stirred for 30 minutes in a bead mill (Fritsch Japan Co., Ltd., planetary type fine grinding mill P-7). The amount of addition of the beads was the same mass as the non-volatile content (total amount of components other than the organic solvent) of the mixed liquid. After stirring, the beads were removed by filtration. Next, a photopolymerization initiator in the amount (unit: parts by mass) shown in Table 1 was added to the obtained mixture, and the resulting mixture was stirred and mixed to obtain each of coating liquids 1A to 7A for forming the first adhesive layer.

First adhesive films (first adhesive films 1A to 7A) including first adhesive layers 1A to 7A, respectively, were obtained by using the obtained coating liquids 1A to 7A. Specifically, first, a coating liquid was applied on a base material film (manufactured by DuPont Teijin Films, Ltd., trade name “PUREX A54”) with a small-sized precision coating apparatus (Yasui Seiki, Inc.) such that the film thickness after drying was 4.5 μm. Next, the coating film was dried (80° C./10 min) in a clean oven (manufactured by ESPEC Corporation), and thus a first adhesive film including a first adhesive layer was obtained.

TABLE 1

| | | First adhesive layer | | | | | | |
|---|---|---|---|---|---|---|---|---|
| | | 1A | 2A | 3A | 4A | 5A | 6A | 7A |
| Liquid epoxy resin | YX7110B80 | 2.3 | 2.4 | 2.4 | 2.4 | 2.5 | 2.6 | 2.7 |
| | YL983U | — | — | — | — | — | — | 3.1 |
| Solid epoxy resin | EP1032 | 27.7 | 28.9 | 28.9 | 28.9 | 29.7 | 31.4 | 29.9 |
| Imidazole-based curing | 2PHZ-PW | 1.4 | 1.4 | 1.4 | — | — | — | — |
| agent | 2MAOK-PW | — | — | — | 1.4 | 1.5 | 1.6 | 1.6 |
| Phenoxy resin | ZX-1356-2 | 13.8 | 14.4 | 14.4 | 14.4 | 14.8 | 15.7 | 16.5 |
| Acrylic compound | A-DPH | 10 | 7.8 | 7.8 | 7.8 | 6.4 | 3.4 | 3.6 |
| Photopolymerization | Omnirad 184 | 0.15 | — | 0.117 | — | — | — | — |
| initiator | Omnirad 819 | 0.03 | 0.117 | 0.023 | 0.117 | 0.1 | 0.05 | — |
| | Omnirad 127 | — | — | — | — | — | — | 0.1 |
| Organic filler | EXL-2655 | 4.6 | 4.8 | 4.8 | 4.8 | 4.9 | 5.2 | 5.5 |
| Silica filler | KE-180G-HLA | 40.1 | 40.1 | 40.1 | 40.1 | 40.1 | 40.1 | 37.0 |

| | | | | |
|---|---|---|---|---|
| Epoxy resin:Acrylic compound | 7.5:2.5 | 8:2 | 8.5:1.5 | 9.1:0.9 |

### (Fabrication of Second Adhesive Film)

The components shown in Table 2 were added to an organic solvent (methyl ethyl ketone) such that the NV value reached 60%, and a mixed liquid was obtained. At this time, the amount of addition of each component was set to the amount (unit: parts by mass) shown in Table 2. Thereafter, beads having a diameter of $1.0 mm and beads having a diameter of $2.0 mm were added to the above-described mixed liquid, and the mixture was stirred for 30 minutes in a bead mill (Fritsch Japan Co., Ltd., planetary type fine grinding mill P-7). The amount of addition of the beads was the same mass as the non-volatile content (total amount of components other than the organic solvent) of the mixed liquid. After stirring, the beads were removed by filtration, and a coating liquid 1B and a coating liquid 2B for forming a second adhesive layer were obtained.

The obtained coating liquid 1B was applied on a base material film (manufactured by DuPont Teijin Films, Ltd., trade name “PUREX A54”) with a small-sized precision coating apparatus (Yasui Seiki, Inc.) such that the film thickness after drying was 4.5 μm. Next, the coating film was dried (80° C./10 min) in a clean oven (manufactured by ESPEC Corporation), and thus a second adhesive film 1B including the second adhesive layer 1B was obtained. In addition, a second adhesive film 2B including a second adhesive layer 2B was obtained in the same manner, except that the coating liquid 2B was used instead of the coating liquid 1B.

TABLE 2

| | | Second adhesive layer | |
|---|---|---|---|
| | | 1B | 2E |
| Liquid epoxy resin | YX7110B80 | 6.3 | 2.9 |
| | YL983U | 2.8 | 3.3 |
| Solid epoxy resin | EP1032 | 29.9 | 34.3 |
| Imidazole-based | 2PHZ-PW | 1.1 | — |
| acuring gent | 2MAOK-PW | — | 1.2 |
| Phenoxy resin | ZX-1356-2 | 13.9 | 14.4 |
| Organic filler | EXL-2655 | 5.6 | 5.8 |
| Silica filler | KE-180G-HLA | 39.4 | 37.0 |
| Flux compound | 2-Methylglutaric acid | 1.1 | 1.2 |

### (Fabrication of Film-Shaped Adhesive)

A first adhesive layer and a second adhesive layer were stacked by laminating any one of the first adhesive films 1A to 7A fabricated as described above and the second adhesive film 1B or 2B in the combinations shown in Table 3, and film-shaped adhesives (total thickness 9.0 μm) of Examples 1 to 6 were fabricated. The lamination temperature was set to 50° C.

### Comparative Example 1

A second adhesive film 1B including a second adhesive layer 1B was obtained in the same manner as in the “Fabrication of second adhesive film” in the above-described Examples 1 to 6, and then two layers of the obtained second adhesive layer 1B were stacked thereon to obtain a film-shaped adhesive (total thickness 9.0 μm) of Comparative Example 1 was obtained.

### <Evaluation>

Connected structures (semiconductor devices) were fabricated by the following procedure, by using the film-shaped adhesives obtained in Examples and Comparative Examples. Furthermore, evaluation of the connection reliability (initial conductivity), fillet length, voids, and sealing properties was carried out by the methods described below by using the obtained connected structures. The results are shown in Table 3. The symbol “-” in the table indicates being not evaluated.

### (Fabrication of Connected Structure)

Each of the film-shaped adhesive fabricated in Examples and Comparative Example was cut out into a predetermined size (8 mm in length×8 mm in width×9.0 μm in thickness), and a sample for evaluation was fabricated. Next, the sample for evaluation was stuck to a surface of a semiconductor chip with solder bumps (chip size: 7.3 mm in length×7.3 mm in width×0.15 mm in thickness, bump height: copper pillar+solder total about 40 μm, number of bumps 328), on which the solder bumps were provided (connecting surface), and a laminated body of the evaluation sample and the semiconductor chip with solder bumps was obtained. At this time, in the Examples, the evaluation sample was stuck to the semiconductor chip with solder bumps from the first adhesive layer side (opposite side of the second adhesive layer). Next, in a case where an evaluation sample of an Example was used, the laminated body obtained as described above was irradiated with light from the side of the evaluation sample, and the first adhesive layer was photocured. At this time, the irradiation with light was performed by using a conveyor UV irradiation apparatus CS60 (manufactured by GS YUASA Corporation). The amount of light irradiation was set to 500 mJ/cm² in Examples 1, 3, and 6, and to 250 mJ/cm² in Examples 2, 4, 5, and 7. Next, the above-described laminated body (in the Examples, the laminated body after light irradiation) was mounted on a glass epoxy substrate (glass epoxy base material: 420 μm thick, copper wiring line: 9 μm thick) from the side of the evaluation sample, by using a flip mounting apparatus “FCB3” (manufactured by Panasonic Holdings Corporation, trade name). Mounting was performed under the conditions of setting the pressure-bonding head temperature to 350° C., the pressure-bonding time to 3 seconds, and the pressure-bonding pressure to 0.5 MPa. As a result, a connected structure (semiconductor device) in which a glass epoxy substrate and a semiconductor chip with solder bumps were connected by daisy chain connection, was obtained.

### (Connection Reliability)

The connection reliability (initial conductivity) was evaluated by measuring the connection resistance value of the connected structure obtained as described above by using a multimeter (manufactured by ADVANTEST Corporation, trade name “R6871E”). A case in which the connection resistance value was 60.0Ω or more and 80.0Ω or less was rated as “A”; a case in which the connection resistance value was more than 80.0Ω and 100Ω or less was rated as “B”; and a case in which the connection resistance was more than 100Ω, a case in which the connection resistance was less than 60.0Ω, and a case in which the resistance value was not displayed due to connection failure, were all rated as “C”. When the rating was B, it was determined that the connection reliability was sufficient, and when the rating was A, it was determined that the connection reliability was satisfactory.

### (Fillet Amount)

The connected structure obtained as described above was observed from the semiconductor chip side by using a digital microscope VHX-6000 (manufactured by Keyence Corporation), and the length of adhesive protruding from the four sides around the semiconductor chip (fillet) was measured. As the length of the fillet on each side, the maximum value of the shortest distance from the edge of the protruding adhesive to the semiconductor chip was employed. The fillet amount was evaluated based on the average value of the length of fillet measured at each of the four sides. When the average value was less than 100 μm, it was determined that the amount of fillet generated had been sufficiently reduced. The numerical value in the table represents an average value of the length of the above-described fillet.

### (Voids)

For the connected structure obtained as described above, images of the external appearance were taken by using an ultrasonic diagnostic imaging apparatus (trade name “Insight-300”, manufactured by Insight Diagnostic Imaging Corporation), an image of the adhesive layer (layer formed of a cured product of the film-shaped adhesive for semiconductors) on the chip was captured using a scanner GT-9300UF (manufactured by EPSON Corporation, trade name), void portions were identified by color tone correction and two-tone conversion using image processing software Adobe Photoshop (registered trademark), and a proportion occupied by the void portions was calculated by using a histogram. When taking the area of the adhesive portion on the chip as 100%, a case in which the void generation ratio was 5% or less was rated as “A”, a case in which the void generation ratio was more than 5% and 10% or less was rated as “B”, and a case in which the void generation ratio was more than 10% was rated as “C”.

### (Sealing Properties)

The connected structure obtained as described above was observed from the semiconductor chip side by using a semiconductor/FPD inspection microscope MX63 (manufactured by OLYMPUS Corporation), and the lengths of unfilled portions at the four corners of the chip were measured. For the length of an unfilled portion, the maximum value of the shortest distances from the four corners of the chip. The sealing properties were rated as “A” when the length of the unfilled portion was less than 500 μm, and as “B” when the length was less than 1000 μm.

TABLE 3

| | | | | | | | | Comparative |
|---|---|---|---|---|---|---|---|---|
| | Example 1 | Example 2 | Example 3 | Example 4 | Example 5 | Example 6 | Example 7 | Example 1 |
| First adhesive | 1A | 2A | 3A | 4A | 5A | 6A | 7A | — |
| Second adhesive | 1B | 1B | 1B | 1B | 1B | 1B | 2B | — |
| Fillet amount (μm) | 57.7 | 90.7 | 80.8 | 69.7 | 74.6 | 83.5 | 85.5 | 143.9 |
| Voids | — | — | — | — | — | A | A | C |
| Sealing properties | — | — | — | — | — | A | A | A |

### REFERENCE SIGNS LIST

1, 1a: film-shaped adhesive for semiconductors, 2, 2a: first adhesive region, 3, 3a: second adhesive region, 4: base material, 5: connecting part (first connecting part), 9: base, 10: connecting part (first connecting part), 11: semiconductor device, 15: wiring line (first connecting part and second connecting part), 20: semiconductor chip, 25: base, 30: connecting bump, 32: bump (first connecting part and second connecting part), 40: sealing part, 100, 200, 500: semiconductor device, A: semiconductor wafer, A′: semiconductor chip.

1. A film-shaped adhesive for semiconductors, comprising a first adhesive region and a second adhesive region along a thickness direction,
wherein the first adhesive region has photocurability and thermosetting properties, and
the second adhesive region has thermosetting properties but does not have photocurability.

2. The film-shaped adhesive for semiconductors according to claim 1, wherein the first adhesive region comprises a photopolymerizable compound, a photopolymerization initiator, a thermosetting resin, and a thermal curing agent.

3. The film-shaped adhesive for semiconductors according to claim 2, wherein the photopolymerizable compound is a radically polymerizable compound, and the photopolymerization initiator is a photoradical polymerization initiator.

4. The film-shaped adhesive for semiconductors according to claim 3, wherein the radically polymerizable compound comprises a (meth)acrylic compound.

5. The film-shaped adhesive for semiconductors according to claim 2, wherein the thermosetting resin comprises an epoxy resin.

6. The film-shaped adhesive for semiconductors according to claim 5, wherein the thermal curing agent comprises an imidazole-based curing agent.

7. The film-shaped adhesive for semiconductors according to claim 6, wherein the imidazole-based curing agent has a triazine ring.

8. The film-shaped adhesive for semiconductors according to claim 2, wherein a ratio of a content of the thermosetting resin with respect to a content of the photopolymerizable compound in the first adhesive region is 3 to 11 in terms of mass ratio.

9. The film-shaped adhesive for semiconductors according to claim 1, wherein the second adhesive region comprises a thermosetting resin, a thermal curing agent, and a flux compound.

10. The film-shaped adhesive for semiconductors according to claim 9, wherein the flux compound has two or more carboxy groups.

11. The film-shaped adhesive for semiconductors according to claim 1, wherein the second adhesive region has a thickness of 0.5 to 2 times a thickness of the first adhesive region.

12. The film-shaped adhesive for semiconductors according to claim 1, wherein the film-shaped adhesive is used for joining a semiconductor chip and a base and sealing a gap between the semiconductor chip and the base.

13. A method for producing the film-shaped adhesive for semiconductors according to claim 1, the method comprising:
providing any one of a first adhesive layer having photocurability and thermosetting properties and a second adhesive layer having thermosetting properties but not having photocurability, on the other.

14. An adhesive tape comprising:
the film-shaped adhesive for semiconductors according to claim 1; and
a back grinding tape provided on the film-shaped adhesive for semiconductors, the back grinding tape being provided on an opposite side of the first adhesive region side as viewed from the second adhesive region.

15. A method for producing a semiconductor device, the method comprising:
irradiating the first adhesive region of the film-shaped adhesive for semiconductors according to claim 1 with light; and
heating and joining a semiconductor chip and a base in a state in which the semiconductor chip and the base are arranged, with the film-shaped adhesive for semiconductors after light irradiation interposed therebetween, such that connecting parts thereof face each other,
wherein the light is irradiated in a state in which the film-shaped adhesive for semiconductors is stuck, from a side of the first adhesive region, to a connecting surface of the semiconductor chip or a precursor thereof, or a connecting surface of the base or a precursor thereof.

16. The method for producing a semiconductor device according to claim 15, further comprising:
preparing an adhesive tape including the film-shaped adhesive for semiconductors and a back grinding tape provided on the film-shaped adhesive for semiconductors, the back grinding tape being provided on an opposite side of the first adhesive region side as viewed from the second adhesive region;
sticking the adhesive tape to a connecting surface of a precursor of the semiconductor chip or a precursor of the base from a side of the film-shaped adhesive for semiconductors; and
grinding the precursor to which the adhesive tape is stuck, from an opposite side of the adhesive tape.

17. The method for producing a semiconductor device according to claim 16, wherein the light irradiation is carried out after removing the back grinding tape after grinding the precursor.

18. A semiconductor device comprising:
a semiconductor chip having a first connecting part;
a base having a second connecting part electrically connected to the first connecting part; and
a sealing part joining the semiconductor chip and the base and filling a gap between the semiconductor chip and the base,
wherein the sealing part is a cured product of the film-shaped adhesive for semiconductors according to claim 1.
